(19) United States
(12) Patent Application Publication
(10) Pub. No.: US 2023/0378397 A1
(43) Pub. Date: Nov. 23, 2023

(54) LIGHT EMITTING ELEMENT, METHOD FOR FABRICATING THE SAME AND DISPLAY DEVICE

(71) Applicant: Samsung Display Co., LTD., Yongin-si (KR)

(72) Inventors: Hyung Seok KIM, Yongin-si (KR); Si Sung KIM, Yongin-si (KR); Jong Jin LEE, Yongin-si (KR); Dong Gyun KIM, Yongin-si (KR); Dong Eon LEE, Yongin-si (KR); Hyun Min CHO, Yongin-si (KR); Sang Wook HAN, Yongin-si (KR)

(21) Appl. No.: 18/192,577

(22) Filed: Mar. 29, 2023

(30) Foreign Application Priority Data
May 18, 2022 (KR) 10-2022-0060527

(51) Int. Cl. H01L 33/38; H01L 33/20; H01L 25/075

(52) U.S. Cl. CPC H01L 33/382; H01L 33/20; H01L 25/0753

(57) ABSTRACT

A light emitting element includes: a light emitting element core including a first semiconductor layer, a light emitting layer on the first semiconductor layer, and a second semiconductor layer on the light emitting layer; and a first element insulating layer surrounding a side surface of the light emitting element core. An outer surface of the first element insulating layer has a first outer surface adjacent to one surface of the first semiconductor layer, the one surface of the first semiconductor layer being opposite to another surface of the first semiconductor layer facing the second semiconductor layer, and a second outer surface farther away from a side surface of the first semiconductor layer than the first outer surface is.

### CROSS-REFERENCE TO RELATED APPLICATION

This application claims priority to and the benefit of Korean Patent Application No. 10-2022-0060527, filed on May 18, 2022, in the Korean Intellectual Property Office (KIPO), the entire content of which is incorporated herein by reference.

### BACKGROUND

### 1. Field

Aspects of embodiments of the present disclosure relate to a light emitting element, a method for fabricating the light emitting element, and a display device.

### 2. Description of the Related Art

The importance of display devices is increasing with the development of multimedia. In response to this, various types of display devices, such as an organic light emitting display (OLED) and a liquid crystal display (LCD), are being used.

A device for displaying an image of a display device includes a display panel, such as an organic light emitting display panel or a liquid crystal display panel. The display panel may include a light emitting element, and the light emitting element may be a light emitting diode (LED). The light emitting diode includes the organic light emitting diode (OLED) using an organic material as a light emitting material and an inorganic light emitting diode using an inorganic material as a light emitting material.

### SUMMARY

Aspects and features of embodiments of the present disclosure provide a light emitting element with improved step difference of the separation surface of the light emitting element and a method for manufacturing the same in the process of separating the light emitting element from the lower substrate.

Aspects and features of embodiments of the present disclosure provide a display device including a light emitting element in which a step difference of a separation surface is improved.

However, embodiments of the present disclosure, and aspects and features thereof, are not limited to those set forth herein. The above and other embodiments of the present disclosure, and aspects and features thereof, will become more apparent to one of ordinary skill in the art to which the present disclosure pertains by referencing the detailed description of the present disclosure given below.

According to an embodiment of the present disclosure, a light emitting element includes: a light emitting element core including a first semiconductor layer, a light emitting layer on the first semiconductor layer, and a second semiconductor layer on the light emitting layer; and a first element insulating layer surrounding a side surface of the light emitting element core. An outer surface of the first element insulating layer has a first outer surface adjacent to one surface of the first semiconductor layer, the one surface of the first semiconductor layer being opposite to another surface of the first semiconductor layer facing the second semiconductor layer, and a second outer surface farther away from a side surface of the first semiconductor layer than the first outer surface is.

The other surface of the first semiconductor layer may have a concave shape toward a center of the first semiconductor layer.

A first diameter of the first element insulating layer having the first outer surface may be smaller than a second diameter of the first element insulating layer having the second outer surface.

The light emitting element may further include a second element insulating layer between the light emitting element core and the first element insulating layer and surrounding the side surface of the light emitting element core. A side surface of the first semiconductor layer may be in contact with both the first element insulating layer and the second element insulating layer.

The first element insulating layer may have a first lower surface between the first outer surface and the one surface of the first semiconductor layer and a second lower surface between the first outer surface and the second outer surface.

A first distance, which is a maximum distance between a first lower surface of the first element insulating layer and the other surface of the first semiconductor layer, may be greater than a second distance, which is a maximum distance between a first lower surface of the first element insulating layer and a lower surface of the second element insulating layer.

The first distance and the second distance may be about 100 nm or less.

A first distance, which is a maximum distance between a first lower surface of the first element insulating layer and the other surface of the first semiconductor layer, may be the same as a second distance, which is a maximum distance between a first lower surface of the first element insulating layer and a lower surface of the second element insulating layer.

A first distance, which is a maximum distance between a first lower surface of the first element insulating layer and the other surface of the first semiconductor layer, may be greater than a second distance, which is a maximum distance between a first lower surface of the first element insulating layer and a second lower surface of the first element insulating layer.

One surface of the second element insulating layer may be covered by the first element insulating layer.

The side surface of the first semiconductor layer may have a first side surface in contact with the first element insulating layer and a second side surface in contact with the second element insulating layer, and the first side surface may be nearer to the other surface of the first semiconductor layer than the second side surface is.

A first thickness of the first element insulating layer having the first outer surface may be the same as a second thickness of the first element insulating layer having the second outer surface.

A first thickness of the first element insulating layer at the first outer surface may be less than a second thickness of the first element insulating layer at the second outer surface.

The light emitting element core may further include an element electrode layer on the second semiconductor layer, and a side surface of the element electrode layer may protrude outwardly from a side surface of the first semiconductor layer.

According to another embodiment of the present disclosure, a method for fabricating the light emitting element includes: forming a first stacked structure including a first semiconductor material layer, a light emitting material layer, and a second semiconductor material layer on a substrate; forming a second stacked structure including a first semiconductor layer, a light emitting layer, and a second semiconductor layer by etching the first stacked structure in a direction perpendicular to the substrate; forming a first element insulating layer surrounding an outer surface of the first semiconductor layer; a first etching of etching an inclined surface of the first semiconductor layer exposed by the first element insulating layer; forming a second element insulating layer on a first side surface of the first semiconductor layer exposed through the first etching and a second side surface surrounded by the first element insulating layer; and separating the first semiconductor layer from the substrate.

The inclined surface of the first semiconductor layer may be inclined by about 120° to about 140° from the substrate.

The separating the first semiconductor layer from the substrate may include forming a remaining first semiconductor layer on the substrate.

The remaining first semiconductor layer may include a protrusion protruding from an upper surface of the substrate to have a height of 100 nm or less.

The first side surface and the second side surface of the first semiconductor layer may be vertically aligned with the substrate.

The forming of the second element insulating layer may include: forming the second element insulating layer on an upper surface of the first semiconductor layer exposed between adjacent ones of the second stacked structures; and etching the second element insulating layer on the upper surface of the first semiconductor layer.

An etching process of the second element insulating layer may be a dry etching method, and an etching process of the inclined surface of the first semiconductor layer may be a wet etching method.

According to another embodiment of the present disclosure, a display device includes: a first electrode and a second electrode on a substrate and spaced apart from each other; and a light emitting element between the first electrode and the second electrode. The light emitting element includes: a first semiconductor layer; a light emitting layer on the first semiconductor layer; a light emitting element core comprising a second semiconductor layer on the light emitting layer; and a first element insulating layer surrounding a side surface of the light emitting element core. The first element insulating layer has a first outer surface adjacent to one surface of the first semiconductor layer, the one surface of the first semiconductor layer being opposite to another surface of the first semiconductor layer facing the second semiconductor layer, and a second outer surface farther away from a side surface of the first semiconductor layer than the first outer surface is.

The display device may further include a first connection electrode in contact with a first end of the light emitting element and a second connection electrode in contact with a second end of the light emitting element. The second end of the light emitting element and the second connection electrode may be concave toward a center of the light emitting element.

According to the aforementioned and other embodiments of the present disclosure, an element insulating layer surrounding the outer surface of the light emitting element may be included. The element insulating layer may protrude further outwardly from the other end of the light emitting element, which is opposite to the one end thereof that is the separation surface of the light emitting element.

According to the aforementioned and other embodiments of the present disclosure, a step difference at the separation surface of the light emitting element may be improved by forming an element insulating film surrounding the outer surface of the light emitting element and then etching the exposed semiconductor layer. Accordingly, the luminous efficiency of the light emitting element may be improved.

### BRIEF DESCRIPTION OF THE DRAWINGS

The above and other aspects and features of the present disclosure will become more apparent by describing embodiments thereof with reference to the attached drawings, in which:

FIG. 1 is a schematic perspective view of a light emitting element according to an embodiment.

FIG. 2 is a cross-sectional view of a light emitting element according to an embodiment.

FIG. 3 is an enlarged cross-sectional view of the area X of FIG. 2.

FIG. 4 is another example of an enlarged cross-sectional view of the area X of FIG. 2.

FIG. 5 is a cross-sectional view of a light emitting element according to another embodiment.

FIG. 6 is an enlarged cross-sectional view of the area Y of FIG. 5.

FIG. 7 is a cross-sectional view of a light emitting element according to another embodiment.

FIGS. 8 to 21 are views and images illustrating a method of manufacturing a light emitting element according to an embodiment.

FIG. 22 is an image of a light emitting element according to an embodiment and a light emitting element according to a comparative example.

FIG. 23 is a plan view of a display device according to an embodiment.

FIG. 24 is a plan layout view illustrating one pixel of a display device according to an embodiment.

FIG. 25 is a cross-sectional view taken along the line I-I′ of FIG. 24.

FIG. 26 is an enlarged cross-sectional view of the area A of FIG. 25.

FIG. 27 is an enlarged cross-sectional view illustrating the area A of FIG. 25 according to another embodiment.

### DETAILED DESCRIPTION

Aspects and features of embodiments of the present disclosure, and methods of accomplishing the same, may be understood more readily by reference to the detailed description of embodiments and the accompanying drawings. Hereinafter, embodiments will be described in more detail with reference to the accompanying drawings. The described embodiments, however, may be embodied in various different forms and should not be construed as being limited to the embodiments illustrated herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions but such be understood to include deviations in shapes that result from, for instance, manufacturing.

For example, an implanted region illustrated as a rectangle may have rounded or curved features and/or a gradient of implant concentration at its edges rather than a binary change from implanted to non-implanted region. Similarly, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Further, in this specification, the phrase “on a plane,” or “in a plan view,” means viewing a target portion from the top, and the phrase “on a cross-section” means viewing a cross-section formed by vertically cutting a target portion from the side.

In the present disclosure, the x-axis, the y-axis, and/or the z-axis are not limited to three axes of a rectangular coordinate system and may be interpreted in a broader sense. For example, the x-axis, the y-axis, and the z-axis may be perpendicular to one another or may represent different directions that are not perpendicular to one another. The same applies for first, second, and/or third directions.

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

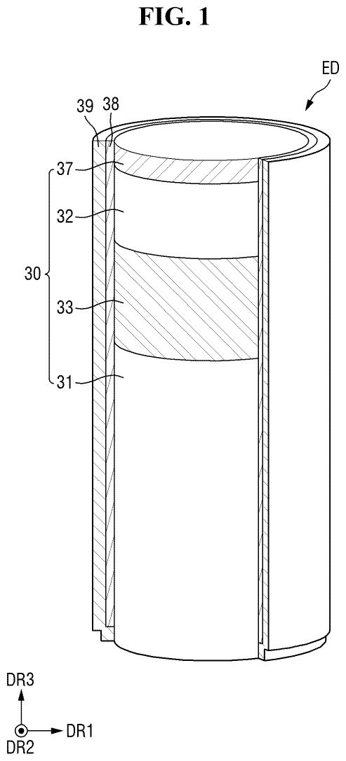

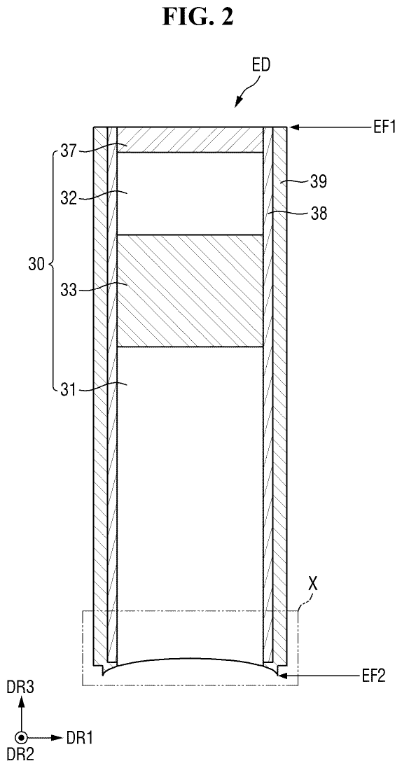

FIG. 1 is a schematic perspective view of a light emitting element according to an embodiment. FIG. 2 is a cross-sectional view of a light emitting element according to an embodiment.

Referring to FIGS. 1 and 2, the light emitting element ED is a particle type element and may have a rod or cylindrical shape having an aspect ratio (e.g., a predetermined aspect ratio). The light emitting element ED has a shape extending in one direction (e.g., the third direction DR3), and a length of the light emitting element ED in the extending direction (or longitudinal direction, DR3) is greater than a diameter of the light emitting element ED. For example, the light emitting element ED may have a shape such as a cylinder, a rod, a wire, a tube, etc., may have a polygonal prism shape such as a cube, a cuboid, or a hexagonal prism, or may have an outer surface partially inclined although extended in one direction. Hereinafter, to describe the shape of the light emitting element ED as shown in the drawings, the terms “one direction DR3”, the “extension direction DR3 of the light emitting element ED”, and the “longitudinal direction DR3 of the light emitting element ED” may be used interchangeably. The first direction DR1 and the second direction DR2 may be defined as horizontal directions crossing the longitudinal direction DR3 of the light emitting element ED. The first direction DR1 and the second direction DR2 may be perpendicular to each other.

The light emitting element ED may have a size of a nano-meter scale (e.g., about 1 nm or more and less than about 1 μm) to a micro-meter scale (e.g., about 1 μm or more and less than about 1 mm). Although not limited thereto, the length of the light emitting element ED in the extending direction DR3 is, in one embodiment, in a range of about 1 to about 10 μm, such as in a range of about 4 μm to about 5 μm, and the diameter of the light emitting element ED may be about 500 nm. The aspect ratio of the light emitting element ED may be in a range of about 1.2:1 to about 100:1 but is not limited thereto.

In an embodiment, the light emitting element ED may be an inorganic light emitting diode made of an inorganic material. The inorganic light emitting diode may include a plurality of semiconductor layers. For example, the inorganic light emitting diode may include a first conductivity type (e.g., n-type) semiconductor layer, a second conductivity type (e.g., p-type) semiconductor layer, and an active semiconductor layer interposed therebetween. The active semiconductor layer receives holes and electrons from the first conductivity-type semiconductor layer and the second conductivity-type semiconductor layer, respectively, and the holes and electrons may combine with each other in the active semiconductor layer to emit light. In addition, the inorganic light emitting diode may be aligned between the two electrodes in which the polarity is formed when an electric field is generated in a specific direction between the two electrodes facing each other.

The light emitting element ED may include a light emitting element core 30, a first element insulating layer 38, and a second element insulating layer 39. The light emitting element core 30 may have a shape extending in one direction DR3. The light emitting element core 30 may have a rod or cylindrical shape. However, the present disclosure is not limited thereto, and the light emitting element core 30 may have a polygonal shape, such as a cube, a rectangular parallelepiped, or a hexagonal pillar, or may have an outer surface partially inclined although extended in one direction.

The light emitting element core 30 may include a first semiconductor layer 31, a second semiconductor layer 32, a light emitting layer 33, and an element electrode layer 37. The first semiconductor layer 31, the light emitting layer 33, the second semiconductor layer 32, and the element electrode layer 37 may be sequentially stacked along one direction DR3, which is the longitudinal direction of the light emitting element core 30.

Hereinafter, “upper” indicates the side on which the element electrode layer 37 is disposed with respect to the light emitting element core 30 in one direction DR3, “upper surface” indicates a surface facing one side in one direction DR3 in embodiments describing the light emitting element ED, unless otherwise stated. In addition, “lower” indicates the side on which the first semiconductor layer 31 is disposed with respect to the light emitting element core 30 in the other side opposite to the one direction DR3, and “lower surface” indicates the surface facing towards the other side in the one direction DR3. An upper portion of the light emitting element ED may be referred to as a first end, and a lower portion of the light emitting element ED may be referred to as a second end. An upper surface of the light emitting element ED may be referred to as a first end surface EF1 or one surface, and a lower surface of the light emitting element ED may be referred to as a second end surface EF2 or the other surface.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, 0≤x+y≤1). For example, the first semiconductor layer 31 may be any one or more of AlGaInN, GaN, AlGaN, InGaN, AlN, and InN doped with an n-type dopant. The n-type dopant doped in the first semiconductor layer 31 may be Si, Ge, Sn, Se, or the like. The first semiconductor layer 31 may have an upper surface facing the second semiconductor layer 32, a lower surface opposite to the upper surface, and a side surface.

The second semiconductor layer 32 is disposed on the first semiconductor layer 31 with the light emitting layer 33 interposed therebetween. The second semiconductor layer 32 may be a p-type semiconductor, and the second semiconductor layer 32 may include a semiconductor material having a chemical formula of AlₓGa_{y}In_{1-x-y}N (0≤x≤1, 0≤y≤1, 0≤x+y≤1). For example, the second semiconductor layer 32 may be at least one of AlGaInN, GaN, AlGaN, InGaN, AlN, and InN doped with a p-type dopant. The p-type dopant doped in the second semiconductor layer 32 may be Mg, Zn, Ca, Ba, or the like. The second semiconductor layer 32 may have a lower surface facing the first semiconductor layer 31, the upper surface opposite to the lower surface and the upper surface facing the element electrode layer 37, and a side surface.

Although the first semiconductor layer 31 and the second semiconductor layer 32 are illustrated as each being one layer, the present disclosure is not limited thereto. Depending on the material of the light emitting layer 33, the first semiconductor layer 31 and the second semiconductor layer 32 may include a greater number of layers, for example, a clad layer or a TSBR (Tensile strain barrier reducing) layer. For example, the light emitting element ED may further include another semiconductor layer disposed between the first semiconductor layer 31 and the light emitting layer 33 or between the second semiconductor layer 32 and the light emitting layer 33. The semiconductor layer disposed between the first semiconductor layer 31 and the light emitting layer 33 may be any one or more of AlGaInN, GaN, AlGaN, InGaN, AlN, InN and SLs doped with the n-type dopant and the semiconductor layer disposed between the second semiconductor layer 32 and the light emitting layer 33 may be any one or more of AlGaInN, GaN, AlGaN, InGaN, AlN, and InN doped with the p-type dopant.

The light emitting layer 33 is disposed between the first semiconductor layer 31 and the second semiconductor layer 32. The light emitting layer 33 may include a material having a single or multiple quantum well structure. When the light emitting layer 33 includes the material having a multi-quantum well structure, it may have a structure in which a quantum layer and a well layer are alternately stacked. The light emitting layer 33 may emit light by combining electron-hole pairs according to an electric signal applied through the first semiconductor layer 31 and the second semiconductor layer 32. The light emitting layer 33 may include a material such as AlGaN, AlGaInN, or InGaN. When the light emitting layer 33 has a multi-quantum well structure in which quantum layers and well layers are alternately stacked, the quantum layer may include a material such as AlGaN or AlGaInN, and the well layer may include a material such as GaN or AlInN.

The light emitting layer 33 may have a structure in which a semiconductor material having a large band gap energy and a semiconductor material having a small band gap energy are alternately stacked and may include other Group III to Group V semiconductor materials according to the wavelength band of light to be emitted. The light emitted by the light emitting layer 33 is not limited to the light in the blue wavelength band, and in some embodiments, light in the red and green wavelength bands may be emitted.

The light emitted from the light emitting layer 33 may be emitted not only from both end surfaces in one direction DR3, which is the longitudinal direction of the light emitting element ED, but may also be emitted from the side surfaces of the light emitting element ED. In other words, the light emitted from the light emitting layer 33 is not limited in one direction.

In this specification, the first end, which is the upper portion (or upper end) of the light emitting element ED, may be the upper portion of the second semiconductor layer 32 and the second end, which is a lower portion (or lower surface) of the light emitting element ED, may be a lower portion of the first semiconductor layer 31. The first end surface EF1, that is, the upper surface of the light emitting element ED may include the upper surface of the second semiconductor layer 32, and the second end surface EF2, that is, the lower surface of the light emitting element ED may include the lower surface of the first semiconductor layer 31. In some embodiments, when the light emitting element ED includes the element electrode layer 37, the first end of the light emitting element ED may be the upper portion of the element electrode layer 37 and the first end surface EF1 of the light emitting element ED may be the top surface of the element electrode layer 37. Side surfaces of the first semiconductor layer 31, the light emitting layer 33, and the second semiconductor layer 32 may be arranged in parallel in one direction DR3.

The element electrode layer 37 may be an ohmic connection electrode. However, the present disclosure is not limited thereto, and the element electrode layer 37 may be a Schottky connection (or contact) electrode. The light emitting element ED may include at least one element electrode layer 37. The light emitting element ED may include one or more element electrode layers 37 but is not limited thereto, and in some embodiments, the element electrode layer 37 may be omitted.

The element electrode layer 37 may be disposed between the second semiconductor layer 32 and the electrode (e.g., an external electrode) to reduce resistance when both ends of the light emitting element ED and the electrode are electrically connected to each other to apply an electric signal to the first semiconductor layer 31 and the second semiconductor layer 32. The element electrode layer 37 may include a conductive metal. For example, the element electrode layer 37 may include at least one of aluminum (Al), titanium (Ti), indium (In), gold (Au), silver (Ag), ITO, IZO, and ITZO.

The first element insulating layer 38 is disposed to surround a side surface (e.g., an outer circumferential surface) of the light emitting element core 30. For example, the first element insulating layer 38 may be extended in the longitudinal direction DR3 to surround side surfaces of the plurality of semiconductor layers and/or element electrode layer(s) 37. The first element insulating layer 38 may be disposed to surround at least the outer surface of the light emitting layer 33, and both end surfaces EF1 and EF2 in the longitudinal direction DR3 of the light emitting element ED may be exposed. In addition, the first element insulating layer 38 may be formed to have a round top surface in a cross-section in a region adjacent to at least one end of the light emitting element ED.

The first element insulating layer 38 may include materials having insulating properties, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). Although the first element insulating layer 38 is illustrated as being a single layer, the present disclosure is not limited thereto. In some embodiments, the first element insulating layer 38 may be formed in a multi-layered structure in which a plurality of layers are stacked.

The first element insulating layer 38 may protect the semiconductor layers and the element electrode layer 37 of the light emitting element ED. The first element insulating layer 38 may prevent an electrical short that may occur in the light emitting layer 33 when the first element insulating layer 38 is in direct contact with an electrode through which an electrical signal is transmitted to the light emitting element ED. In addition, the first element insulating layer 38 may prevent a decrease in the luminous efficiency of the light emitting element ED.

The second element insulating layer 39 may be disposed on an outer surface (e.g., an outer circumferential surface) of the first element insulating layer 38. The second element insulating layer 39 may be disposed to surround an outer surface of the first element insulating layer 38. The first element insulating layer 38 may be disposed between the light emitting element core 30 and the second element insulating layer 39.

The second element insulating layer 39 may extend in one direction DR3 in which the light emitting element core 30 extends. The second element insulating layer 39 may be disposed to cover the side surface of the light emitting element core 30 while exposing both end surfaces EF1 and EF2 of the light emitting element core 30, similar to the first element insulating layer 38. The second element insulating layer 39 is illustrated as extending in the longitudinal direction DR3 of the light emitting element ED to cover from the first semiconductor layer 31 to the side surface of the element electrode layer 37 but is not limited thereto.

The second element insulating layer 39 may include materials having insulating properties, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). The second element insulating layer 39 may have (or may be formed of) a single layer including the above-described material or a multilayer structure in which one or more of these materials are stacked. The second element insulating layer 39 may protect the semiconductor layers and the element electrode layer 37 of the light emitting element ED, similar to the first element insulating layer 38.

In some embodiments, an outer surface of the first element insulating layer 38 and/or the second element insulating layer 39 may be surface-treated. The light emitting element ED may be sprayed onto the electrode in a state of being dispersed in an ink and then aligned. The outer surface of the first element insulating layer 38 and/or the second element insulating layer 39 may be treated with hydrophobicity or hydrophilicity for the light emitting element ED to maintain in a dispersed state without being agglomerated with other adjacent light emitting elements ED in the ink.

The first element insulating layer 38, according to an embodiment, extends in the longitudinal direction DR3, which is the extending (or extension) direction of the light emitting element ED, and may be exposed without covering the side surface of the first semiconductor layer 31 in a region adjacent to the second end, that is, a lower portion of the light emitting element ED. The exposed side surface of the first semiconductor layer 31 may be covered by the second element insulating layer 39. The second element insulating layer 39 may be in contact with a side surface of the first semiconductor layer 31 that is not covered by the first element insulating layer 38. The side surface of the first semiconductor layer 31 may be in contact with both the first element insulating layer 38 and the second element insulating layer 39.

Because the first element insulating layer 38 does not cover the lower side surface of the first semiconductor layer 31, the second element insulating layer 39 disposed on the first element insulating layer 38 may have a step difference according to the shape of the first element insulating layer 38. For example, the second element insulating layer 39 may have a stepped shape protruding outwardly from the light emitting element ED from the lower portion to the upper side of the light emitting element ED according to the shape of the first element insulating layer 38. The second element insulating layer 39 may include a portion protruding in the first direction DR1 and the second direction DR2 along the longitudinal direction DR3.

Although not limited thereto, a length of the first element insulating layer 38 in one direction DR3 may be longer than a length of the second element insulating layer 39 in one direction DR3.

The light emitting element ED, according to an embodiment, may have a shape in which a lower surface, that is, the second end surface EF2 is concave toward the inside of (e.g., the center of) the light emitting element ED. The second end surface EF2 may include the lower surface of the first semiconductor layer 31 and the lower surface of the second element insulating layer 39.

In the manufacturing process of the light emitting element ED, which will be described in more detail later, a surface damage region DR formed during a first etching process for etching a first semiconductor structure to form a second semiconductor structures may be removed through a third etching process, that is, a first wet etching process and a fifth etching process, that is, a second wet etching process. The surface damage region DR may cause the step difference between the second end surface EF2, that is, the separation surface of the light emitting element ED in the process of separating the light emitting element ED from the remaining first semiconductor layer. The step may have a length difference of about 200 nm or more and may cause an abnormal profile of the second end surface EF2. Accordingly, when a second connection electrode contacts the second end surface EF2 of the light emitting element ED, a contact failure may occur or a contact area may decrease in the alignment process of a display device 10.

According to embodiments of the present disclosure, the step difference of the second end surface EF2 of the light emitting element ED may be improved (e.g., reduced) and an abnormal profile may be minimized because the removal rate of the surface damage region DR is increased. The light emitting efficiency of the light emitting element ED and the display device 10 may be improved by mitigating a contact defect of the display device 10 including the light emitting element ED.

The removal rate of the surface damage region DR may be improved by increasing (e.g., lengthening) the period of the wet etching process after forming a second semiconductor structure 3002, but the outer surface of the semiconductor layer of the second semiconductor structure 3002 may be etched together. According to embodiments of the present disclosure, after performing the third etching process, the first element insulating layer 38 may be formed, and after performing the fifth etching process, the second element insulating layer 39 may be formed to improve the removal rate of the surface damage region DR and to maintain the outer surface protection and diameter of the light emitting element core 30. Accordingly, the light emitting efficiency of the light emitting element ED and the display device 10 including the same may be improved.

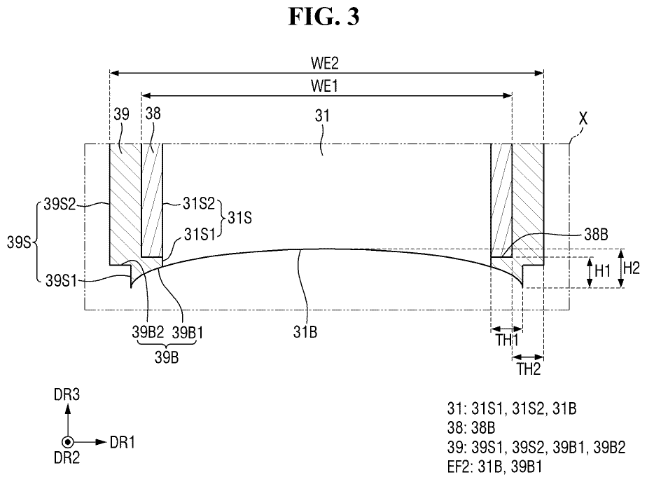

The structure of the second end of the light emitting element ED, according to the manufacturing method, will be described in detail with reference to FIG. 3.

FIG. 3 is an enlarged cross-sectional view of the area X of FIG. 2.

Referring to FIG. 2 and FIG. 3, the first semiconductor layer 31, the first element insulating layer 38, and the second element insulating layer 39 may be disposed at the second end of the light emitting element ED.

The first semiconductor layer 31 may have a bottom surface 31B and a side surface 31S. The bottom surface 31B of the first semiconductor layer 31 may occupy most of the second end surface EF2 of the light emitting element ED. The bottom surface 31B of the first semiconductor layer 31 may have the concave shape toward the inside of (e.g., the center of) the first semiconductor layer 31. For example, the bottom surface 31B of the first semiconductor layer 31 may have a center portion and an edge portion away from the center portion. The central portion of the bottom surface 31B may be closer to the light emitting layer 33 than the edge portion of the bottom surface 31B is. A first distance H1, which is the maximum distance between the lowermost end of the light emitting element ED (a first bottom surface 39B1 of the second element insulating layer 39 in the drawing) and the bottom surface 31B of the first semiconductor layer 31, may be about 100 nm or less. For example, the concave degree of the first semiconductor layer 31 may be approximately 100 nm.

The side surface 31S of the first semiconductor layer 31 may have a first side surface 31S1 and a second side surface 31S2. The first side surface 31S1 and the second side surface 31S2 of the first semiconductor layer 31 are substantially parallel to each other, and the first side surface 31S1 and the second side surface 31S2 may be connected to each other. The first side surface 31S1 may be disposed lower than the second side surface 31S2. For example, the first side surface 31S1 may be closer to the second end surface EF2 of the light emitting element ED than the second side surface 31S2 is. The first side surface 31S1 of the first semiconductor layer 31 may be connected between the bottom surface 31B and the second side surface 31S2. The first side surface 31S1 of the first semiconductor layer 31 may be surrounded by the first element insulating layer 38 and the second element insulating layer 39, and the second side surface 31S2 may be surrounded by the second element insulating layer 39. The first side surface 31S1 of the first semiconductor layer 31 may be in contact with the first element insulating layer 38, and the second side surface 31S2 may be in contact with the second element insulating layer 39.

The first element insulating layer 38 may have an inner surface, an outer surface, and a bottom surface 38B. The inner surface of the first element insulating layer 38 may be in contact with the first semiconductor layer 31, the light emitting layer 33, and the second semiconductor layer 32 of the light emitting element core 30. The outer surface of the first element insulating layer 38 may be in contact with the inner surface of the second element insulating layer 39. The bottom surface 38B of the first element insulating layer 38 may not form the second end surface EF2 of the light emitting element ED.

The bottom surface 38B of the first element insulating layer 38 may be covered by the second element insulating layer 39. The first element insulating layer 38 is disposed to surround the portion of the side surface 31S of the first semiconductor layer 31 but may expose the other area(s). For example, the first element insulating layer 38 may expose the first side surface 31S1 of the first semiconductor layer 31 and may surround the second side surface 31S2. A second distance H2, which is the maximum distance between the lowermost end of the light emitting element ED (the first bottom surface 39B1 of the second element insulating layer 39 in the drawing) and the bottom surface 38B of the first element insulating layer 38, may be about 100 nm or less.

The second element insulating layer 39 may have the inner surface, the outer surface 39S, and the bottom surface 39B. The inner surface of the second element insulating layer 39 may be in contact with the first element insulating layer 38 and the first semiconductor layer 31.

The outer surface 39S of the second element insulating layer 39 may have a first outer surface 39S1 and a second outer surface 39S2. The first outer surface 39S1 and the second outer surface 39S2 are physically separated from each other and may be connected through a second bottom surface 39B2 of the second element insulating layer 39. The first outer surface 39S1 may be disposed lower than the second outer surface 39S2 of the light emitting element ED. For example, the first outer surface 39S1 may be closer to the second end surface EF2 of the light emitting element ED than the second outer surface 39S2 is. Because the outer surface 39S of the second element insulating layer 39 is formed to have the same thickness on the first side surface 31S1 of the first semiconductor layer 31 and the outer surface of the first element insulating layer 38, it may be divided into the first outer surface 39S1 and the second outer surface 39S2 according to their step difference. The second outer surface 39S2 may protrude to the outside of the light emitting element core 30 farther than the first outer surface 39S1. A first diameter WE1 of the second element insulating layer 39 at the first outer surface 39S1 may be greater than a second diameter WE2 of the second element insulating layer 39 at the second outer surface 39S2.

The bottom surface 39B of the second element insulating layer 39 may have the first bottom surface 39B1 and the second bottom surface 39B2. The first bottom surface 39B1 may be spaced apart from the second bottom surface 39B2. The first bottom surface 39B1 may be included in (e.g., may partially form) the second end surface EF2 of the light emitting element ED. The lowermost end of the light emitting element ED may be the lowermost end of the first bottom surface 39B1 of the second element insulating layer 39. The first bottom surface 39B1 may be disposed lower than the bottom surface 31B of the first semiconductor layer 31. The second bottom surface 39B2 of the second element insulating layer 39 may connect the first outer surface 39S1 and the second outer surface 39S2 of the second element insulating layer 39.

The second bottom surface 39B2 may be disposed above the first bottom surface 39B1.

In an embodiment, the thickness of the second element insulating layer 39 may be constant (or substantially constant). For example, a first thickness TH1 near the first outer surface 39S1 of the second element insulating layer 39 may be substantially the same as a second thickness TH2 near the second outer surface 39S2.

The first distance H1 may be greater than the second distance H2. For example, the maximum height (e.g., the first distance H1) of the bottom surface 31B of the first semiconductor layer 31 based on the lowermost end of the light emitting element ED may be greater than the height (e.g., the second distance H2) of the bottom surface 38B of the first element insulating layer 38.

A length of the first side surface 31S1 of the first semiconductor layer 31 in the longitudinal direction DR3 may be shorter than a length of the second side surface 31S2. A length of the first element insulating layer 38 may be shorter than a length of the second element insulating layer 39. A length of the first outer surface 39S1 of the second element insulating layer 39 may be shorter than a length of the second outer surface 39S2.

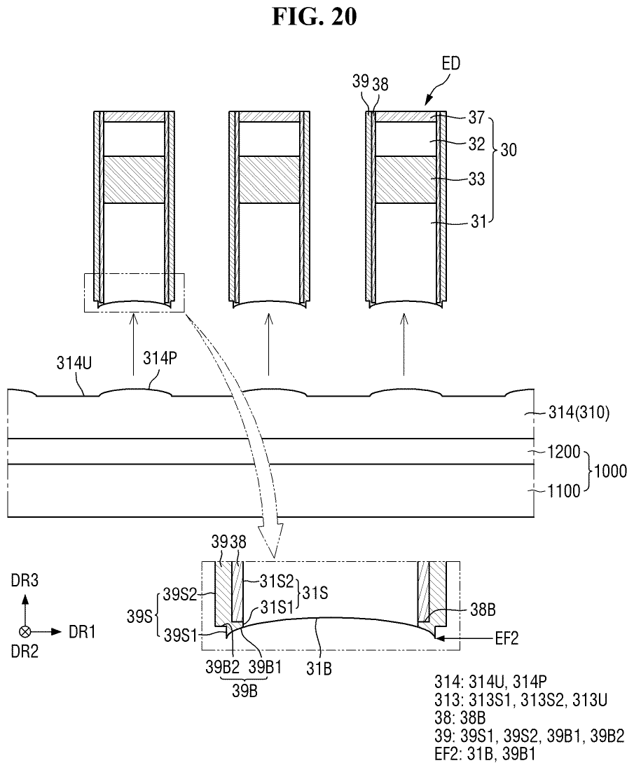

In an embodiment, the second end surface EF2 of the light emitting element ED may have (e.g., may be formed by) the bottom surface 31B of the first semiconductor layer 31 and the first bottom surface 39B1 of the second element insulating layer 39. The second end surface EF2 of the light emitting element ED may have the concave shape toward the inside of (e.g., the center of) the light emitting element ED. The second end surface EF2 of the light emitting element ED may have a semi-elliptical shape concave from the edge to the center. A center of the bottom surface 31B of the first semiconductor layer 31, which is a part of the second end surface EF2, is the uppermost end of the second end surface EF2 of the light emitting element ED, and the lowermost end of the first bottom surface 39B1 of the second element insulating layer 39 may be the lowermost end of the second end surface EF2 of the light emitting element ED. The second end surface EF2 of the light emitting element ED may be formed in the process of separating the light emitting element ED from the remaining first semiconductor layer (see, e.g., 314 in FIG. 20). This is because the adhesion of GaN at the edge of the first semiconductor layer 31 in contact with the first and second element insulating layers 38 and 39 is higher than that of GaN at the center of the first semiconductor layer 31. Because the first semiconductor layer 31 may be more easily separated at the central portion having relatively lower adhesive strength than the edge portion in the separation process, the depression degree of the central portion may be greater. The depression degree (or depth) may be about 100 nm or less.

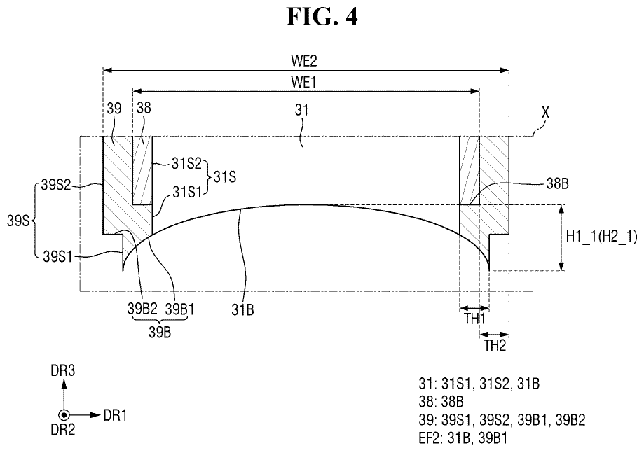

FIG. 4 is an enlarged cross-sectional of the area X of FIG. 2 according to another embodiment.

In the light emitting element ED according to an embodiment, the maximum height of the bottom surface 31B of the first semiconductor layer 31 may be the same as the height of the bottom surface 38B of the first element insulating layer 38 based on the first bottom surface 39B1 of the second element insulating layer 39, which is the lowermost end of the light emitting element ED. That is, a first distance H1_1, which is the maximum distance between the bottom surface 31B of the first semiconductor layer 31 and the first bottom surface 39B1 of the second element insulating layer 39, may be same as a second distance H2_1, which is the maximum distance between the bottom surface 38B of the first element insulating layer 38 and the first bottom surface 39B1 of the second element insulating layer 39. The first distance H1_1 and the second distance H2_1 may be about 100 nm or less.

The embodiment shown in FIG. 4 differs from the previous embodiment shown in FIG. 3 in that the first distance H1 and the second distance H2 are different in the embodiment shown in FIG. 3, while the other aspects remain the same, so a repeated description thereof will be omitted.

Hereinafter, a light emitting element ED_1 according to another embodiment will be described. In the following description, the same components as those of the previously described embodiments are referred to by the same reference numerals, overlapping descriptions will be omitted or simplified, and differences therebetween will be primarily described.

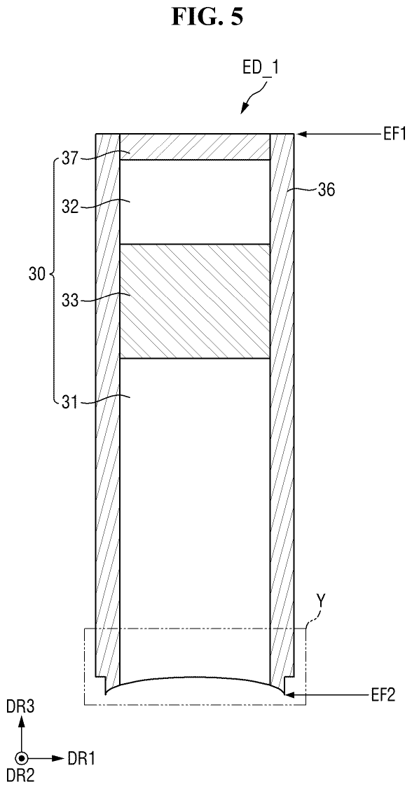

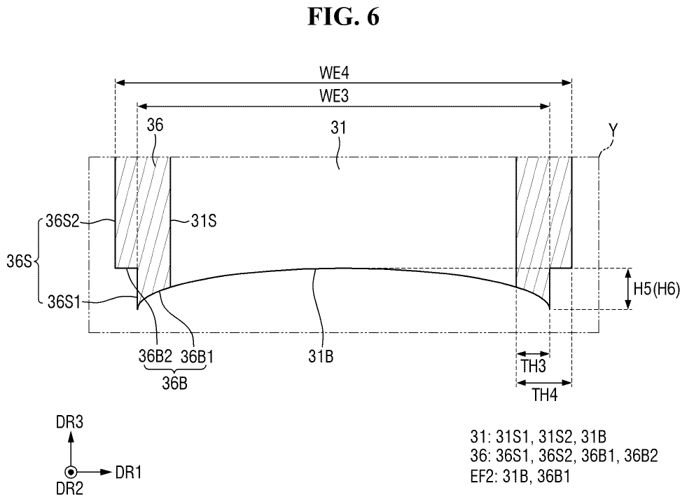

FIG. 5 is a cross-sectional view of a light emitting element according to another embodiment. FIG. 6 is an enlarged cross-sectional view of the area Y of FIG. 5.

Referring to FIGS. 5 and 6, the light emitting element ED_1 according to an embodiment may include the light emitting element core 30 and an element insulating layer 36. The light emitting element core 30 may include the first semiconductor layer 31, the second semiconductor layer 32, the light emitting layer 33, and the element electrode layer 37.

The element insulating layer 36 may be disposed to surround the outer surface of the light emitting element core 30. The element insulating layer 36 may be formed through the same manufacturing method as the first element insulating layer 38 and the second element insulating layer 39 in the light emitting element ED according to the previous embodiment. According to an embodiment, the first element insulating layer 38 and the second element insulating layer 39 contain the same material. Therefore, the insulating layer may be referred to as a single element insulating layer 36 when the boundary between the first element insulating layer 38 and the second element insulating layer 39 is not divided.

The element insulating layer 36 may be extended in the longitudinal direction DR3 to surround side surfaces of the plurality of semiconductor layers or element electrode layers 37. The first element insulating layer 38 may be disposed to surround at least the outer surface of the light emitting layer 33. The element insulating layer 36 may be formed to expose both end surfaces EF1 and EF2 of the light emitting element ED in the longitudinal direction DR3.

The element insulating layer 36 may include the same insulating materials as those of the first element insulating layer 38 and the second element insulating layer 39 described above with reference to FIG. 3.

Referring to FIG. 6, the first semiconductor layer 31 may have the side surface 31S and the bottom surface 31B. Different from the previous embodiment, the side surface 31S of the first semiconductor layer 31 is covered with the same element insulating layer 36 without division of regions and may be in contact with the element insulating layer 36.

The element insulating layer 36 may have a first bottom surface 36B1, a second bottom surface 36B2, a first outer surface 36S1, and a second outer surface 36S2.

The first bottom surface 36B1 of the element insulating layer 36 may be included in (e.g., may form) the second end surface EF2 of the light emitting element ED as in the previous embodiment. The first bottom surface 36B1 may form the second end surface EF2 of the light emitting element ED together with the bottom surface 31B of the first semiconductor layer 31.

The second bottom surface 36B2 of the element insulating layer 36 may connect the first outer surface 36S1 and the second outer surface 36S2 as in the previous embodiment. The second bottom surface 36B2 may be disposed above the first bottom surface 36B1 of the light emitting element ED.

The first outer surface 36S1 of the element insulating layer 36 may be disposed lower than the second outer surface 36S2 of the light emitting element ED as in the previous embodiment. The second outer surface 36S2 may protrude to the outside of the first semiconductor layer 31 farther than the first outer surface 36S1. The element insulating layer 36 may have the stepped shape protruding outwardly from the light emitting element ED from the lower portion to the upper portion of the light emitting element ED in the longitudinal direction DR3. The element insulating layer 36 may have a portion protruding in the first direction DR1 and the second direction DR2 along the longitudinal direction DR3. A third diameter WE3 of the element insulating layer 36 in the region of the first outer surface 36S1 may be greater than a fourth diameter WE4 of the element insulating layer 36 in the region of the second outer surface 36S2.

In one embodiment, the thickness of the element insulating layer 36 may be different for each location. For example, a third thickness TH3 near the first outer surface 36S1 of the element insulating layer 36 may be less than a fourth thickness TH4 near the second outer surface 36S2. A thickness difference between the third thickness TH3 and the fourth thickness TH4 may be the same as the thickness of the element insulating layer 36 that is primarily deposited according to a manufacturing process.

The second end surface EF2 of the light emitting element ED may include the bottom surface 31B of the first semiconductor layer 31 and the first bottom surface 36B1 of the element insulating layer 36. The second end surface EF2 may be concave toward the inside of (e.g., the center of) the light emitting element ED. The central portion of the second end surface EF2 may have a recessed shape recessed from the edge portion of the second end surface EF2. The concave degree (or depth) of the central portion of the second end surface EF2 may be about 100 nm. The drawing illustrates that a maximum height H5 of the bottom surface 31B of the first semiconductor layer 31 and a height H6 of the first bottom surface 36B1 of the element insulating layer 36 from the lowermost end of the light emitting element ED are the same, but the present disclosure is not limited thereto. For example, the maximum height H5 of the bottom surface 31B of the first semiconductor layer 31 may be smaller or greater than the height H6 of the first bottom surface 36B1 of the element insulating layer 36.

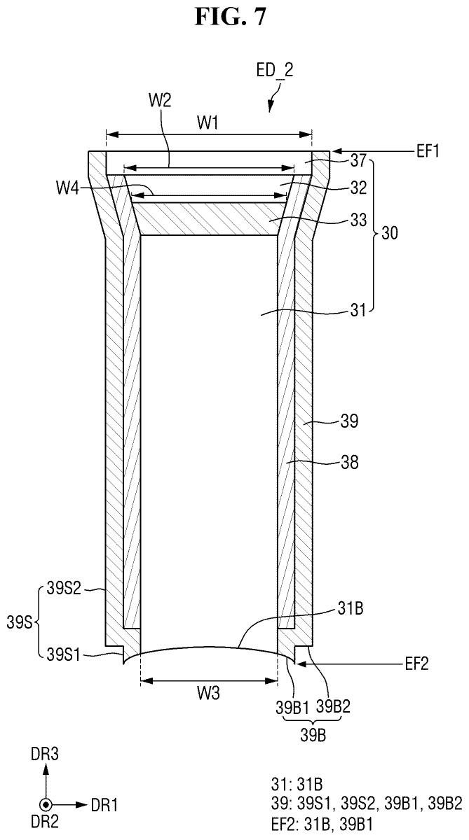

FIG. 7 is a cross-sectional view of a light emitting element according to another embodiment.

A light emitting element ED_2 according to an embodiment is different from the previous embodiments in that the light emitting layer 33 and/or the second semiconductor layer 32 protrude outwardly beyond the first semiconductor layer 31.

For example, the light emitting element ED_2 may include the light emitting element core 30 having the first semiconductor layer 31, the second semiconductor layer 32, the light emitting layer 33, and the element electrode layer 37, the first element insulating layer 38, and the second element insulating layer 39. The first semiconductor layer 31 is the same as in the previous embodiment in that the first semiconductor layer 31 is in contact with both the first element insulating layer 38 and the second element insulating layer 39, the lower surface of the first element insulating layer 38 is covered by the second element insulating layer 39, the second element insulating layer 39 has a step-shaped outer surface 39S, and the second outer surface 39S2 protrudes outwardly from the first outer surface 39S1. In addition, the second end surface EF2 of the light emitting element ED_2 includes (or is formed by) the bottom surface 31B of the first semiconductor layer 31 and the first bottom surface 39B1 of the second element insulating layer 39, and the second end surface EF2 has the shape concave inwardly of the light emitting element ED_2.

The side surface of the element electrode layer 37 may protrude from the side surface of the light emitting element core 30. For example, a diameter W1 of the element electrode layer 37 may be larger than the diameter of the light emitting element core 30 disposed thereunder. The diameter W1 of the element electrode layer 37 may be greater than the maximum diameter W2 of the light emitting element core 30. The first semiconductor layer 31 may have an overall uniform diameter W3 in one direction DR3. A diameter W4 of the upper surface of the light emitting layer 33 may be different from the diameter W3 of the lower surface. The diameter W4 of the upper surface of the light emitting layer 33 may be greater than the diameter W3 of the lower surface and the side surface may have the inclined shape. The diameter W2 of an upper surface of the second semiconductor layer 32 may be different from a diameter W4 of the lower surface of the second semiconductor layer 32. The diameter W2 of the upper surface of the second semiconductor layer 32 may be greater than the diameter W4 of the lower surface, and the side surface of the second semiconductor layer 32 may have the inclined shape. The first element insulating layer 38 may be disposed to completely surround side surfaces of the first semiconductor layer 31, the second semiconductor layer 32, and the light emitting layer 33 of the light emitting element core 30. The first element insulating layer 38 may extend in one direction DR3 and may be formed to cover from the side surface of the first semiconductor layer 31 to the side surface of the light emitting layer 33.

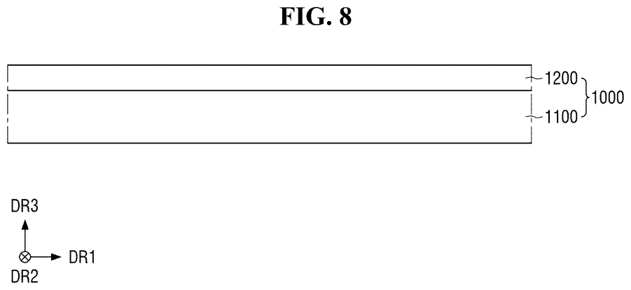

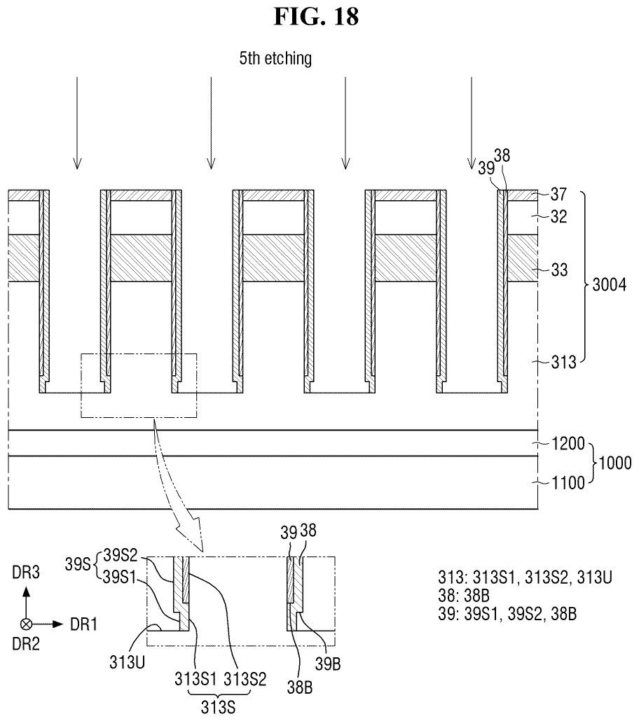

FIGS. 8 to 21 are cross-sectional views illustrating steps of a method of manufacturing a light emitting element according to an embodiment.

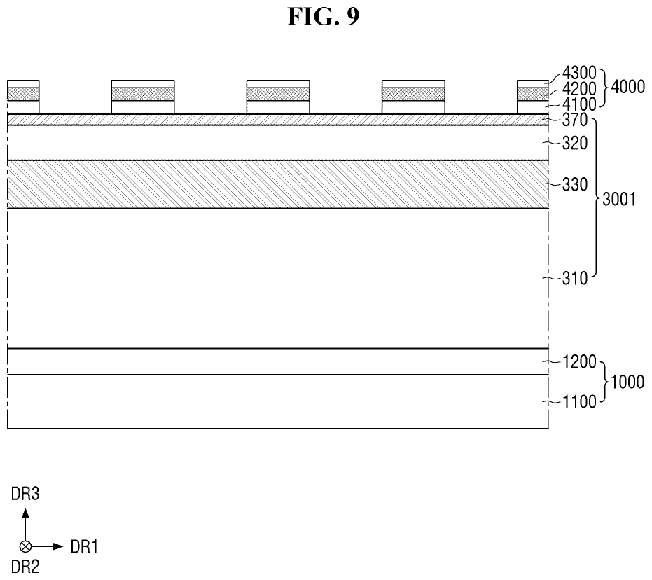

Referring to FIGS. 8 and 9, in describing a manufacturing process of the light emitting element ED according to an embodiment, “upper” refers to a direction in which a plurality of semiconductor layers of the light emitting element ED are stacked from one surface (or upper surface) of the lower substrate 1000 to one side in the third direction DR3, and “upper surface” refers to a surface facing one side of the third direction DR3 unless otherwise specified. In addition, “lower” refers to the other side in the third direction DR3, and “lower side” refers to a surface facing the other side in the third direction DR3.

First, referring to FIG. 8, a lower substrate 1000 is prepared.

The lower substrate 1000 may include a base substrate 1100 and a buffer material layer 1200 disposed on the base substrate 1100.

The base substrate 1100 may include a sapphire substrate (AlₓO_{y}) or a transparent substrate, such as glass. However, the present disclosure is not limited thereto, and the base substrate 1100 may include a conductive substrate, such as GaN, SiC, ZnO, Si, GaP, and GaAs. In an embodiment, the base substrate 1100 may be the sapphire substrate (AlₓO_{y}).

The buffer material layer 1200 may be formed on one surface (or an upper surface) of the base substrate 1100. The buffer material layer 1200 may reduce a lattice constant difference between the base substrate 1100 and a first semiconductor material layer 310 formed thereon.

For example, the buffer material layer 1200 may include an undoped semiconductor. The buffer material layer 1200 may include substantially the same material as the first semiconductor material layer 310 but may be a material not doped with n-type or p-type or may have a doping concentration lower than that of the first semiconductor material layer 310. In an embodiment, the buffer material layer 1200 may be at least one of InAlGaN, GaN, AlGaN, InGaN, AlN, and InN but is not limited thereto.

Next, referring to FIG. 9, a first stacked structure 3001 is formed on the lower substrate 1000. The first stacked structure 3001 includes the first semiconductor material layer 310, a light emitting material layer 330, a second semiconductor material layer 320, and an electrode material layer 370 that are sequentially stacked on a lower substrate 1000.

The plurality of semiconductor material layers grown by an epitaxial method may be formed by growing a seed crystal. The method of forming the semiconductor material layer may be an electron beam deposition method, physical vapor deposition (PVD), chemical vapor deposition (CVD), plasma laser deposition (PLD), dual-type thermal evaporation, sputtering, and metal organic chemical vapor deposition, MOCVD) etc. In one embodiment, the semiconductor material layers may be formed by metal-organic chemical vapor deposition (MOCVD), but the present disclosure is not limited thereto.

The precursor material for forming the semiconductor material layer is not particularly limited within the range of suitable materials that may be usually selected for forming the target material. For example, the precursor material may include a metal precursor including an alkyl group, such as a methyl group or an ethyl group. For example, in an embodiment in which the first semiconductor layer 31, the second semiconductor layer 32, and the light emitting layer 33 are selected from among AlGaInN, GaN, AlGaN, InGaN, AlN, and InN, similar to the light emitting element ED according to an embodiment, the metal precursor may be trimethyl gallium (Ga(CH3)3) or a compound, such as trimethyl aluminum (Al(CH3)3) or triethyl phosphate ((C2H5)3PO4). However, the present disclosure is not limited thereto. The plurality of semiconductor material layers may be formed through a deposition process using the metal precursor and the non-metal precursor.

A plurality of layers included in the first stacked structure 3001 may correspond to respective layers in the light emitting element core 30 according to an embodiment. For example, the first semiconductor material layer 310, the light emitting material layer 330, the second semiconductor material layer 320, and the electrode material layer 370 of the first stacked structure 3001 may respectively correspond to the first semiconductor layer 31, the light emitting layer 33, the second semiconductor layer 32, and the element electrode layer 37 of the light emitting element core 30 and may include the same material as the material included in each layer.

The method further includes forming a mask layer 4000 on the first stacked structure 3001. The mask layer 4000 may include a first insulating mask layer 4100 and a second insulating mask layer 420 disposed on the electrode material layer 370, and mask patterns 4300 disposed on the second insulating mask layer 4200. The mask layer 4000 may have a shape in which the insulating mask layers 4100 and 4200 are etched along a space in which the mask patterns 4300 are spaced apart. The semiconductor material layers 310 and 320, the light emitting material layer 330, and the electrode material layer 370 may be etched at (or according to) the spaced apart spaces between the insulating mask layers 4100 and 4200 and the mask patterns 4300 of the mask layer 4000. A portion of the first stacked structure 3001 that overlaps the portion on which the mask layer 4000 is disposed and is not etched may form the light emitting element core 30 constituting the light emitting element ED.

The first insulating mask layer 4100 and the second insulating mask layer 420 may include an insulating material, and the mask pattern 4300 may include a metal material. For example, the insulating mask layers 4100 and 4200 may be silicon oxide (SiOₓ), silicon nitride (SiNₓ), or silicon oxynitride (SiOₓN_{y}), respectively. The mask pattern 4300 may include a metal, such as chromium (Cr), but is not limited thereto.

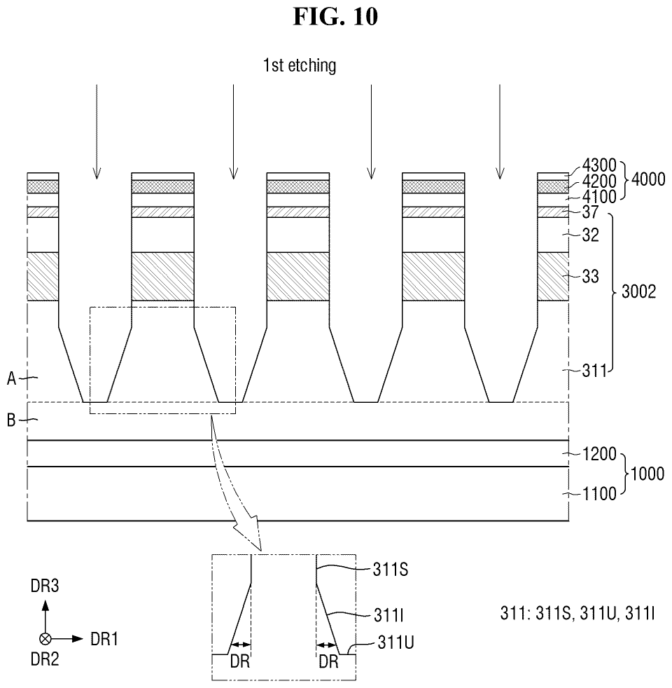

Next, referring to FIG. 10, the first stacked structure 3001 is etched to form a plurality of second stacked structures 3002 spaced apart from each other. Forming the second stacked structure 3002 may include the first etching process for etching the semiconductor material layers 310 and 320, the light emitting material layer 330, and the electrode material layer 370 along the mask layer 4000. The first etching process may be performed in a direction perpendicular to the upper surface of the lower substrate 1000.

The etching process may be a dry etching method, a wet etching method, reactive ion etching (RIE), inductively coupled plasma reactive ion etching (ICP-RIE), or the like. In the case of dry etching, anisotropic etching is possible, which may be suitable for vertical etching. When the above-described etching method is used, the etching etchant may be Cl₂ or O₂. However, the present disclosure is not limited thereto.

Hereinafter, the first semiconductor material layer 310 may be referred to as a first layer 311, a second layer 312, and a third layer 313 according to the manufacturing order of the light emitting element ED. The third layer 313 may form the first semiconductor layer 31 of the light emitting element ED according to a subsequent process. A second stacked structure 3002 is the semiconductor structure including the first layer 311, a third stacked structure 3003 is the semiconductor structure including the second layer 312, and a fourth stacked structure 3004 is the semiconductor structure including the third layer 313 and may be referred to as a light emitting element core 30. The first semiconductor material layer 310 is separated into the first semiconductor layer 31 constituting the light emitting element ED and the remaining first semiconductor layer 314 at the lower end in the separation process of the light emitting element ED (see, e.g., FIG. 20).

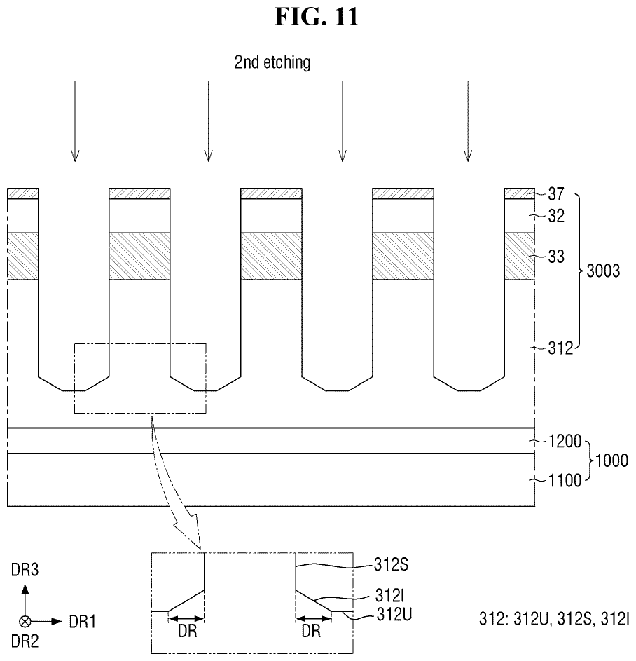

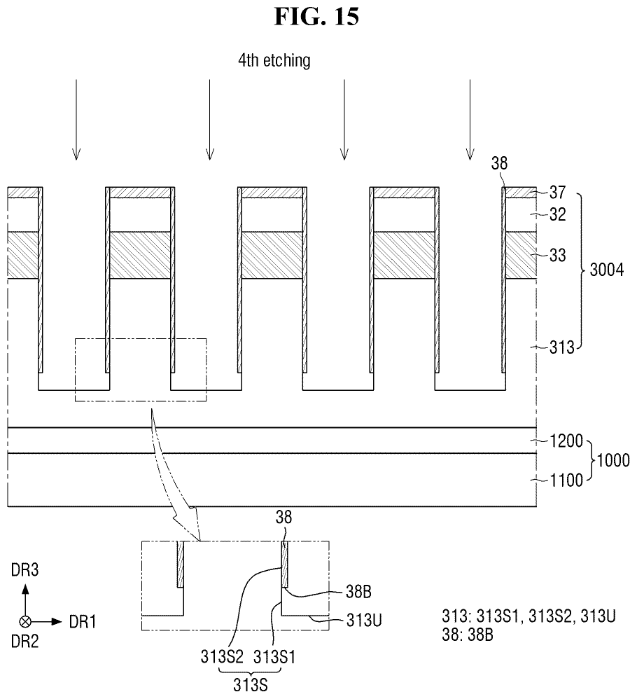

A plurality of second stacked structures 3002 spaced apart from each other may be formed on the base substrate 1000 by the first etching process. The second stacked structure 3002 may include the first layer 311, the light emitting layer 33, the second semiconductor layer 32, and the element electrode layer 37. The first layer 311 may have a first area (A) spaced apart from each other by the first etching process and a second area (B) remaining not completely etched between the second stacked structures 3002. The first area A may form an upper end of the first semiconductor material layer 310, and the second area B may form a lower end of the first semiconductor material layer 310. The first area A may protrude from the second area B in the third direction DR3. As described above, the first area A is separated from the second area B, which is the remaining first semiconductor layer (see, e.g., 314 in FIG. 20) in a subsequent process to constitute the first semiconductor layer 31 of the light emitting element ED, and the second area B may remain on the lower substrate 1000 to constitute the remaining first semiconductor layer 314. It is not limited thereto, however, and the second layer (see, e.g., 312 in FIG. 11) and the third layer (see, e.g., 313 in FIG. 15), which refer to the first semiconductor material layer 310, may also have the first area A spaced apart from each other and the second area B connecting the first area(s) A.

The second stacked structure 3002 may have the shape in which the side surface of the first layer 311 is partially inclined. The first layer 311 may have the shape that increases in width toward the bottom. For example, the first layer 311 may have a partially trapezoidal shape in cross-section cut in the third direction DR3. The first layer 311 may include a surface damage region DR. The surface damage region DR disposed on the outer surface of the first layer 311, which is a region in which a defect is generated in the semiconductor material as a byproduct in the first etching process of etching the first stacked structure 3001, so defects in the semiconductor material may increase toward a lower portion of the second stacked structure 3002. The side surface of the first layer 311 may have the shape that increases in width toward the lower portion due to the surface damage region DR.

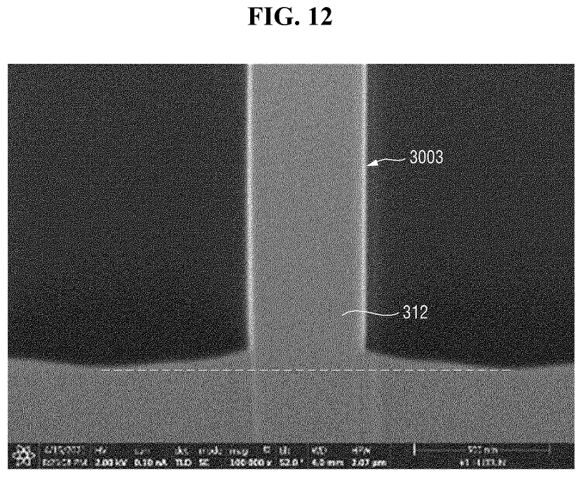

Next, referring to FIGS. 11 and 12, the third stacked structure 3003 is formed so that a portion of the side surface of the second layer 312 is perpendicular to the lower substrate 1000 by etching the second stacked structure 3002. The third stacked structure 3003 may be formed through a second etching process. The third stacked structure 3003 may include the second layer 312, the second semiconductor layer 32, the light emitting layer 33, and the element electrode layer 37.

The second etching process for forming the third stacked structure 3003 may be performed as the first wet etching. A portion of the surface damage region DR of the second layer 312 may be etched by the second etching process performed by the first wet etching, but a portion of the surface damage region DR may remain.

The second layer 312 may have an upper surface (e.g., atop surface) 312U, a side surface 312S, and an inclined surface 3121. An upper surface 312U of the second layer 312 is a surface remaining between the third stack structures 3003 and may be parallel to the extending direction of the lower substrate 1000. The side surface 312S of the second layer 312 is a surface located in a region from which the surface damage region DR is removed according to the second etching process and may be perpendicular to the upper surface of the lower substrate 1000. The side surface 312S of the second layer 312 may be aligned with side surfaces of the light emitting layer 33 and the second semiconductor layer 32. The inclined surface 3121 of the second layer 312 may be a surface located in a region where the surface damage region DR remains despite the second etching process. The inclined surface 3121 of the second layer 312 may be inclined with an inclination (e.g., a predetermined inclination) between the upper surface 312U and the side surface 312S. The inclined surface 3121 may be inclined by approximately 120° to approximately 140° from the upper surface 312U but is not limited thereto.

FIG. 12 is an actual image of the second layer 312 of the third laminate structure 3003. The second layer 312 may form the inclined surface 3121 in a region where the surface damage region DR is located.

According to an embodiment, when the light emitting element ED is formed by separating the second layer 312 in which the surface damage region DR remains from the remaining first semiconductor layer (see, e.g., 314 in FIG. 20), a portion of the second end surface EF2, which is a separation surface between the second layer 312 and the remaining first semiconductor layer 314, may be damaged to have a step difference of about 200 nm or more. Accordingly, because the surface damage region DR of the second layer 312 is removed through wet etching, the crack of the separation surface may be uniformly formed and the step difference of the separation surface of the light emitting element ED may be improved (e.g., reduced). For example, the removal rate of the surface damage region DR may be improved as the period of the wet etching process increases. However, as the etching period of the second etching process increases, the diameter of the third stacked structure 3003 may decrease. In the present embodiment, the second wet etching process may be performed after the first element insulating layer 38 is formed on the outer surface to prevent the diameters of the second layer 312, the light emitting layer 33, the second semiconductor layer 32, and the element electrode layer 37 of the third stacked structure 3003 from being reduced in the first wet etching process. In other words, after performing the second etching process, which is the first wet etching, the first element insulating layer 38 protecting the outer surface of the third stacked structure 3003 is formed and a fourth etching process, which is a second wet etching, may be performed. The outer surface of the light emitting element ED may be protected by the first element insulating layer 38 and the removal rate of the surface damage region DR may be improved by performing the wet etching multiple times. In a subsequent separation process, the step difference of the separation surface of the light emitting element ED may be improved. Hereinafter, the method of manufacturing the above-described light emitting element ED will be described in detail with further reference to other drawings.

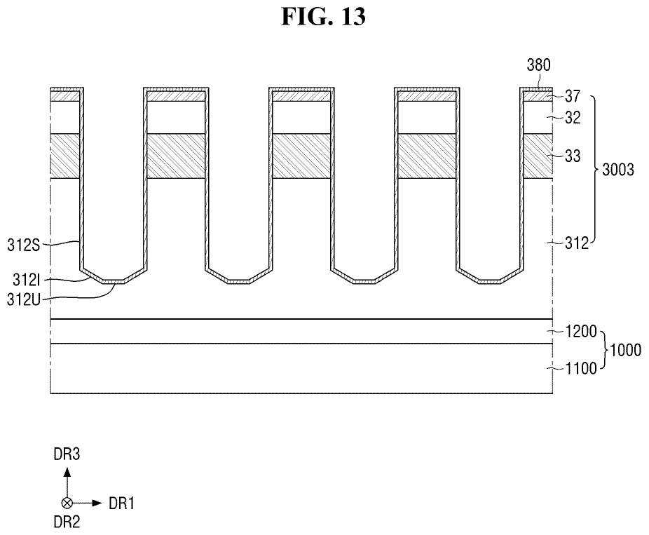

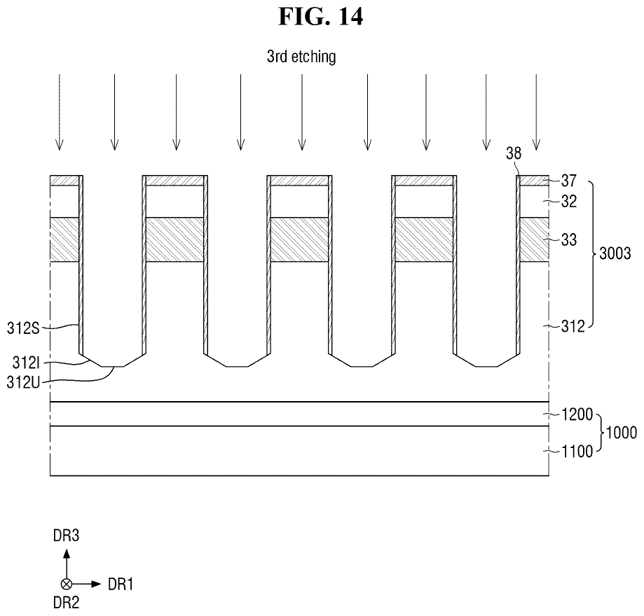

Referring to FIGS. 13 and 14, a first insulating material layer 380 is formed on the third stacked structure 3003. After the first insulating material layer 380 is formed to surround the outer surface of the third stacked structure 3003, the first element insulating layer 38 may be formed by performing the third etching process of partially removing the first insulating material layer 380 to expose the top surface of the third stacked structure 3003.

The first insulating material layer 380 is formed on the entire surface of the lower substrate 1000 and is formed not only on the top and side surfaces of the third stacked structure 3003 but also on the remaining semiconductor layer between the third stacked structures 3003. The first insulating material layer 380 may also be formed on the upper surface 312U and the inclined surface 3121 of the second layer 312. The first insulating material layer 380 may be directly disposed on the top surface and the side surface of the third stacked structure 3003. Accordingly, the first insulating material layer 380 may be directly disposed on side surfaces of the plurality of semiconductor layers of the third stacked structure 3003 to be in contact with them.

The first insulating material layer 380 may be formed using a method of applying or immersing the insulating material on the vertically etched outer surface of the third stacked structure 3003. However, the present disclosure is not limited thereto. For example, the first insulating material layer 380 may be formed by atomic layer deposition (ALD) or chemical vapor deposition (CVD).

In the third etching process of forming the first element insulating layer 38 by partially removing the first insulating material layer 380, a process such as anisotropic dry etching or etch-back may be performed. The upper surface 312U and the inclined surface 3121 of the second layer 312 may be exposed through the third etching process. The side surface 312S of the second layer 312 is surrounded by the first element insulating layer 38 and is referred to as a second side surface 313S2 of the third layer 313 in the subsequent fourth etching process. In an embodiment, because the first element insulating layer 38 protects the outer surface of the third stacked structure 3003, the side surface 312S of the second layer 312, the light emitting layer 33, and the second semiconductor layer 32 may be protected by the first element insulating layer 38 even when the third stacked structure 3003 is etched according to the fourth etching process. The diameter of the third stacked structure 3003 may be substantially the same as the diameter of the light emitting element ED.

In FIG. 14, the upper surface of the element electrode layer 37 is partially exposed and the upper surface of the first element insulating layer 38 is illustrated as being flat, but the present disclosure is not limited thereto. In some embodiments, an outer surface of the first element insulating layer 38 may be partially curved in a region surrounding the element electrode layer 37.

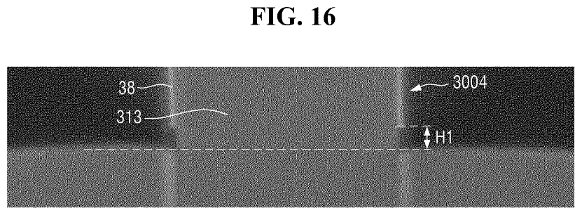

Next, referring to FIGS. 15 and 16, the fourth stacked structure 3004 having a side surface 313S of the third layer 313 extending in a direction perpendicular to the lower substrate 1000 is formed by etching the third stacked structure 3003. The fourth stacked structure 3004 may be formed through the fourth etching process. The fourth stacked structure 3004 may include the third layer 313, the second semiconductor layer 32, the light emitting layer 33, and the element electrode layer 37. The upper end of the third layer 313 may be the final first semiconductor material layer 310 constituting the first semiconductor layer 31 of the light emitting element ED according to the subsequent process.

The fourth etching process for forming the fourth stacked structure 3004 may be performed as the second wet etching. The surface damage region DR of the second layer 312, which remains without being removed in the second etching process, that is, the first wet etching, may be removed and the inclined surface 3121 may be removed (see, e.g., FIG. 11) through the fourth etching process performed by the second wet etching.

The third layer 313 may include an upper surface 313U and a side surface 313S. The inclined surface of the third layer 313 may be removed as the surface damage region DR is etched. The extending direction of the upper surface 313U of the third layer 313 and the extending direction of the side surface 313S of the third layer 313 may meet at one point to form a vertical direction.

The side surfaces 313S of the third layer 313 may be aligned in one direction DR3 without protruding or recessed regions. The side surface 313S of the third layer 313 may have a first side surface 313S1 exposed according to the fourth etching process and the second side surface 313S2 surrounded by the first element insulating layer 38. Because the first side surface 313S1 is formed after the first element insulating layer 38 is disposed, the first side surface 313S1 may be exposed without being covered by the first element insulating layer 38. The second side surface 313S2 may be substantially the same as the side surface 312S of the second layer 312. The second side surface 313S2 may contact the first element insulating layer 38 and may be surrounded by the first element insulating layer 38.

The bottom surface 38B of the first element insulating layer 38, which is the first insulating layer, may be exposed by the fourth etching process.

FIG. 16 is an actual image of the third layer 313 and the first element insulating layer 38 of the fourth stacked structure 3004. In the third layer 313, the surface damage region DR is removed and the side surface 313S and the upper surface 313U may vertically intersect (e.g., may intersect at a right angle or a substantially right angle). The first element insulating layer 38 may expose the first side surface 313S1, which is a part of the side surface 313S of the third layer 313, and may cover the second side surface 313S2. A length H1 of the exposed first side surface 313S1 may be about 100 nm or less. This may be referred to as the first distance H1 in FIG. 3.

According to an embodiment, the removal rate of the surface damage region DR of the first semiconductor material layer 310 may be improved through the fourth etching process. After protecting the outer surface of the third stacked structure 3003, in which the surface damage region DR remains, with the first element insulating layer 38, the surface damage region DR may be removed by performing the fourth etching process, which is the second wet etching process. The inclined surface (e.g., 3121) of the lower end of the first semiconductor material layer 310 may be removed as the surface damage region DR is removed. Accordingly, the side surface (e.g., 313S) and the upper surface (e.g., 313U) of the fourth stacked structure 4004 may vertically intersect. When the fourth stacked structure 4004 from which the inclined surface of the lower end of the first semiconductor material layer 310 is removed is separated from the remaining first semiconductor layer (see, e.g., 314 in FIG. 20), the step difference between the second end surface EF2, that is, the separation surface of the light emitting element ED, may be reduced or minimized.

The second element insulating layer 39, which is the second insulating layer, may be further disposed to protect the side surface of the first semiconductor material layer 310 (e.g., the third layer 313) exposed according to the fourth etching process.

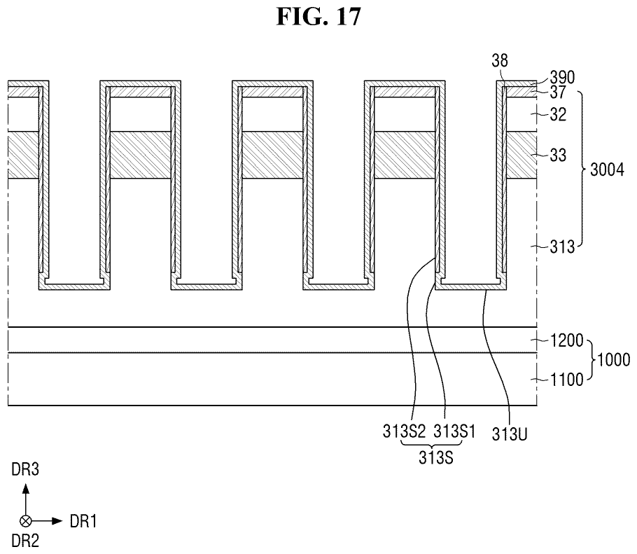

Referring to FIGS. 17 to 19, a second insulating material layer 390 is formed on the fourth stacked structure 3004. The second element insulating layer 39 may be formed by performing the fifth etching process of partially removing the second insulating material layer 390 to expose the upper surface of the fourth stacked structure 3004 after the second insulating material layer 390 is formed to surround the outer surface of the fourth stacked structure 3004.

The second insulating material layer 390 is formed on the entire surface of the lower substrate 1000 and is formed not only on the upper surface and side surfaces of the fourth stacked structure 3004 but also on the remaining semiconductor layer between the fourth stacked structures 3004. The second insulating material layer 390 may also be formed on the upper surface 313U of the third layer 313. The second insulating material layer 390 may contact the first element insulating layer 38 surrounding the side surfaces of the second side surface 313S2, the second semiconductor layer 32, the light emitting layer 33, and the element electrode layer 37 of the third layer 313. In addition, the second insulating material layer 390 may be directly disposed on the first side surface 313S1 of the third layer 313 to be in contact with the third layer 313.

Similar to the first insulating material layer 380, the second insulating material layer 390 may be formed using the method of applying or immersing the insulating material on the outer surface of the vertically etched fourth stacked structure 3004. However, the present disclosure is not limited thereto. For example, the second insulating material layer 390 may be formed by atomic layer deposition (ALD) or chemical vapor deposition (CVD).

The fifth etching process for forming the second element insulating layer 39 by partially removing the second insulating material layer 390 may be anisotropic dry etching or etch-back processes. The upper surface 313U of the third layer 313 may be exposed through the fifth etching process. The first side surface 313S1 of the third layer 313 is in direct contact with the second element insulating layer 39, and the second side surface 313S2 may be surrounded by the second element insulating layer 39 with the first element insulating layer 38 interposed therebetween. The second element insulating layer 39 may protect the first side surface 313S1 of the third layer 313 exposed according to the fourth etching process, that is, the second etching process. The second element insulating layer 39 may cover the bottom surface 38B of the first element insulating layer 38.

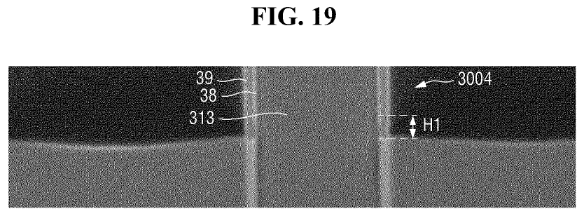

FIG. 19 is an actual image of the fourth stacked structure 3004 covered with the first element insulating layer 38 and the second element insulating layer 39. The third layer 313 may directly contact the first element insulating layer 38 and the second element insulating layer 39. The third layer 313 may be covered by the second element insulating layer 39 by the length H1 of the exposed first side surface 313S1.

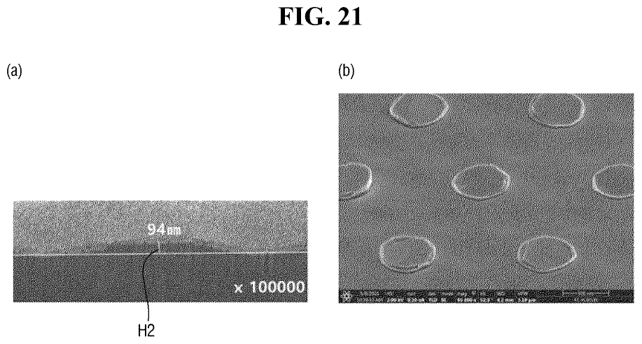

Referring to FIGS. 20 and 21, a fourth stacked structures 4004, in which the first element insulating layer 38 and the second element insulating layer 39 are formed, are separated from the remaining first semiconductor layer 314. The fourth stacked structure 4004 separated from the lower substrate 1000 may form the light emitting element core 30 of the light emitting element ED. The separation process of the fourth stacked structure 4004 may be performed by a physical separation method or a chemical separation method. The shear stress transferred to the light emitting element ED according to the separation process may proceed in a direction parallel to the extending direction of the lower substrate 1000.

The light emitting element ED includes the first element insulating layer 38 and the second element insulating layer 39, and the second end surface EF2 of the light emitting element ED may be concavely formed inwardly of the light emitting element ED and the separation surface of the remaining first semiconductor layer 314 may form a protrusion 314P protruding to the outside. The protrusion 314P of the remaining first semiconductor layer 314 may protrude about 100 nm or less from an upper surface 314U. Because the adhesive force of GaN at the edge of the first semiconductor layer 31 in contact with the first and second element insulating layers 38 and 39 is greater than that of GaN at the center of the first semiconductor layer 31, the first semiconductor layer 31 may be more easily separated from the central portion having relatively lower adhesive strength than the edge portion during the separation process.

According to an embodiment, the abnormal profile of the lower surface of the first semiconductor layer 31 or the step difference of the lower surface of the first semiconductor layer 31 may be improved in the process of separating the first semiconductor layer 31 of the light emitting element core 30 from the remaining first semiconductor layer 314 because the inclined surface of the upper surface 314U of the remaining first semiconductor layer 314 is removed. The lower surface of the first semiconductor layer 31 may be the second end surface EF2 of the light emitting element ED.

The inclination of the upper surface 314U of the remaining first semiconductor layer 314, that is, the lower first semiconductor material layer 310, may be removed by performing the first wet etching process (i.e., the third etching process (3^{th} etching process)), the first insulating layer application process, the second wet etching process (i.e., the fifth etching process (5^{th} etching process)), and the second insulating layer application process. Cracks transmitted to (or formed in) the light emitting element ED during the separation process may be transmitted parallel to the extending direction (e.g., the horizontal direction) of the lower substrate 1000 and the step of the lower surface of the first semiconductor layer 31 may be minimized or may be reduced to about 200 nm or less as the removal rate of the inclined surface of the upper surface 314U of the remaining first semiconductor layer 314 is improved.

FIG. 21 is an actual image of the remaining first semiconductor layer 314. In the image, the protrusion 314P of the remaining first semiconductor layer 314 may protrude about 94 nm from the upper surface 314U. The protruding length H2 of the protrusion 314P may be the same as the second distance H2, which is the recessed length of the second end surface EF2 of the light emitting element ED in FIG. 3.

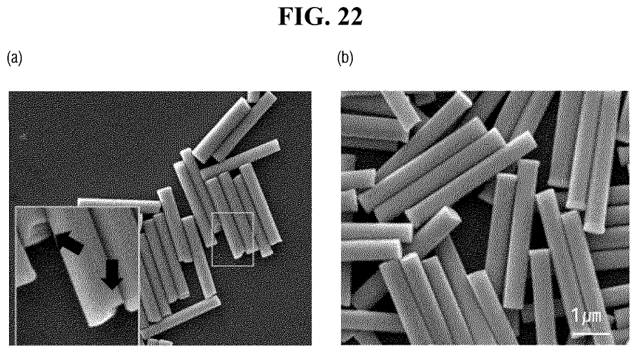

FIG. 22 is an image of a light emitting element according to an embodiment and a light emitting element according to a comparative example. FIG. 22(a) is an image of the light emitting element ED according to the comparative example, and FIG. 22(b) is an image of the light emitting element ED according to an embodiment. Referring to FIG. 22(a), the lower end, which is the separation surface of the light emitting element, may have an abnormal profile including the step difference of about 200 nm or more. In contrast, referring to FIG. 22(b), the light emitting element ED according to embodiments of the present disclosure may have a flat surface with the second end surface EF2 having the relatively small (or low) step difference of about 200 nm or less.

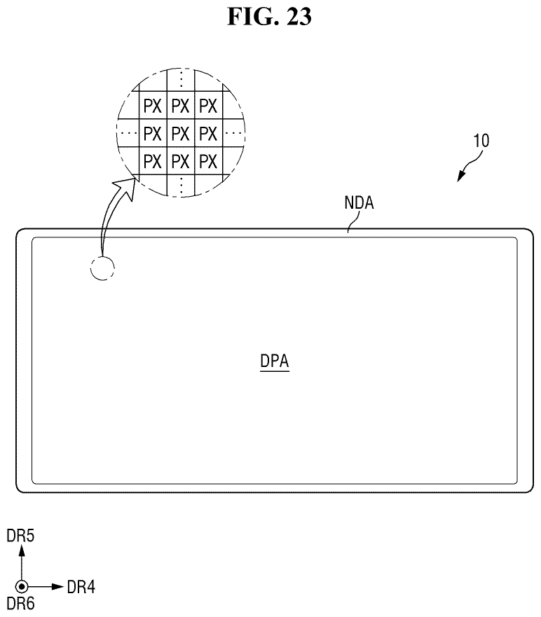

FIG. 23 is a plan view of a display device according to an embodiment.

Referring to FIG. 23, the display device 10 is configured to display a moving image and/or a still image. The display device 10 may represent any electronic device that provides (or includes) a display screen. For example, televisions, laptop, monitor, billboard, internet of Things (IoT) device, mobile phone, smart phone, tablet PC (Personal Computer), electronic watch, smart watch, watch phone, head mounted display, mobile communication terminal, electronic notebook, e-book, PMP (Portable Multimedia Player), navigation, game console, digital camera, camcorder, etc. that provide a display screen may be included in the display device 10.

The display device 10 includes the display panel that provides a display screen. Examples of the display panel include an inorganic light emitting diode display panel, an organic light emitting display panel, a quantum dot light emitting display panel, a plasma display panel, a field emitting display panel, and the like. Hereinafter, the above-described light emitting element ED, specifically, the inorganic light emitting diode display panel, is described as an example of the display panel, but the present disclosure is not limited thereto and the same technical idea may be applied to other display panels if applicable.

Hereinafter, a fourth direction DR4, a fifth direction DR5, and a sixth direction DR6 are defined in the drawings of the display device 10. The fourth direction DR4 and the fifth direction DR5 may be perpendicular to each other in one plane. The sixth direction DR6 may be the direction perpendicular to a plane in which the fourth direction DR4 and the fifth direction DR5 are located. The sixth direction DR6 is perpendicular to each of the fourth direction DR4 and the fifth direction DR5. In describing embodiments of the display device 10, the sixth direction DR6 refers to a thickness direction of the display device 10.

The display device 10 may have a rectangular shape including a long side in the fourth direction DR4 and a short side in the fifth direction DR5 in a plan view. A corner area at where the long side and the short side of the display device 10 meet on the planar view may be a right angle but is not limited thereto and may form a rounded shape. The flat shape of the display device 10 is not limited to the illustrated example and may have other shapes, such as a square, a quadrangle with rounded corners (e.g., vertices), other polygons, or a circle.

The display surface of the display device 10 may be disposed on one side of the sixth direction DR6, that is, the thickness direction. In embodiments describing the display device 10, unless otherwise stated, “upper” refers to a display direction in one side of the sixth direction DR6, and “top” refers to a surface facing one side in the sixth direction DR6. In addition, the “lower” refers to a direction opposite to the display direction as the other side in the sixth direction DR6, and the “lower surface” refers to a surface facing the other side in the sixth direction DR6.

In the present specification, the fourth direction DR4 may be a longitudinal direction (e.g., an extension direction) of the light emitting element ED or a direction parallel to the third direction DR3 corresponding to one direction. For example, the light emitting elements ED extending in the third direction DR3 may be aligned parallel to the fourth direction DR4 of the display device 10.

The display device 10 may have a display area DPA and a non-display area NDA. The display area DPA is an area in which an image may be displayed, and the non-display area NDA is an area in which an image is not displayed.

The shape of the display area DPA may follow (e.g., may correspond to) the shape of the display device 10. For example, the shape of the display area DPA may have the rectangular shape in the plan view, similar to the overall shape of the display device 10. The display area DPA may generally occupy the center of the display device 10.

The display area DPA may include a plurality of pixels PX. The plurality of pixels PX may be arranged in a matrix. The shape of each pixel PX may be a rectangular or square shape in the plan view. However, the present disclosure is not limited thereto, and the shape of each pixel PX may be a rhombus shape in which each side is inclined with respect to one direction. Each pixel PX may be alternately arranged in a stripe type or a PenTile© (a registered trademark of Samsung Display Co., Ltd.) type.

The non-display area NDA may be disposed around the display area DPA. The non-display area NDA may completely or partially surround (e.g., surround in a plan view or extend around a periphery of) the display area DPA. In an embodiment, the display area DPA may have the rectangular shape, and the non-display area NDA may be disposed adjacent to the four sides of the display area DPA. The non-display area NDA may constitute a bezel of the display device 10. Wires included in the display device 10, circuit drivers, or a pad part on which an external device is mounted may be disposed in the non-display area NDA.

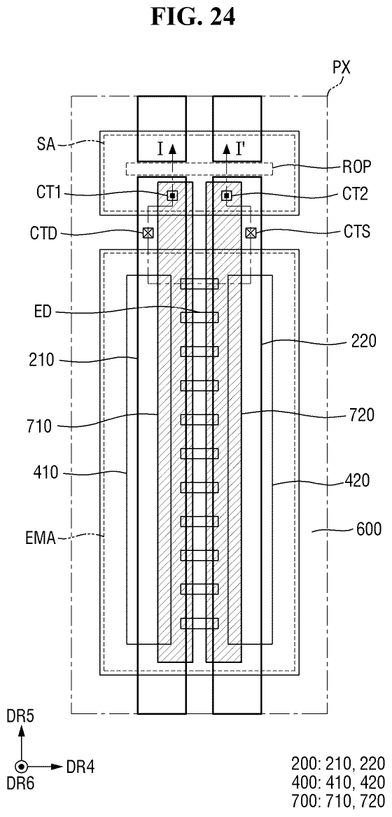

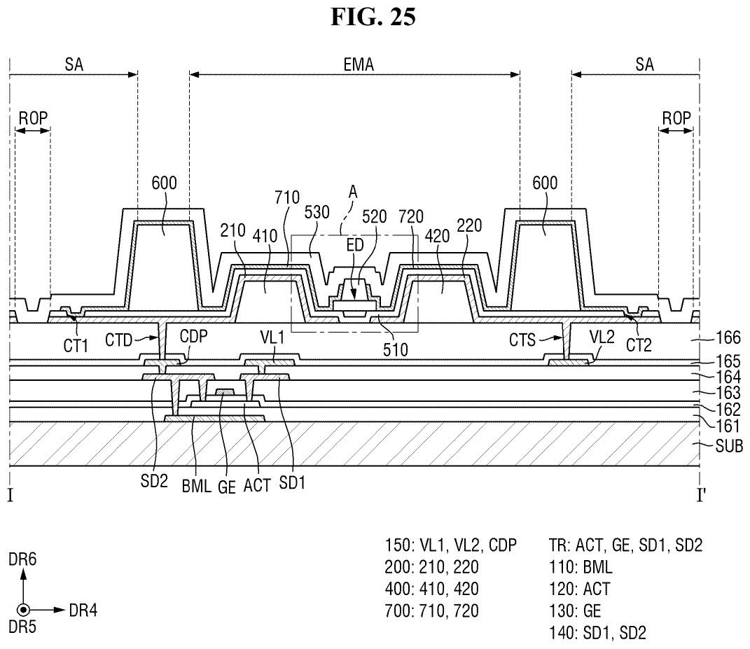

FIG. 24 is a plan layout view illustrating one pixel of a display device according to an embodiment. FIG. 25 is a cross-sectional view taken along the line I-I′ of FIG. 24.

FIG. 24 illustrates a planar arrangement of a first electrode 210, a second electrode 220, first banks 400 (e.g., 410, 420), a second bank 600, a plurality of light emitting elements ED, and connection electrodes 700 (e.g., 710, 720) disposed in one pixel PX of the display device 10.

Referring to FIG. 24, each pixel PX of the display device 10 may have a light emitting area EMA and a non-emission area. The light emitting area EMA may be an area from which light emitted from the light emitting element ED is emitted, and the non-emission area may be defined as an area where the light emitted from the light emitting element ED does not reach and, thus, the light is not emitted.

The light emitting area EMA may include an area in which the light emitting element ED is disposed and an area adjacent thereto. In addition, the light emitting area EMA may further include an area in which light emitted from the light emitting element ED is reflected or refracted by other members to be emitted.

Each pixel PX may also have a sub-area SA disposed in the non-emission area. The light emitting element ED may not be disposed in the sub area SA. The sub-area SA may be disposed above the light emitting area EMA in the plan view in one pixel PX. The sub-area SA may be disposed between the light emitting area EMA of the pixels PX disposed adjacent to each other in the fifth direction DR5. The sub-area SA may have an area in which an electrode layer 200 and a connection electrode 700 are electrically connected to each other through the contact parts CT1 and CT2.

The sub area SA may have a separation part (e.g., a separation area) ROP. The separation part ROP of the sub-area SA may be an area in which the first electrode 210 and the second electrode 220 are respectively separated from each other included in the electrode layer 200 included in each pixel PX adjacent to each other along the fifth direction DR5.

Referring to FIGS. 24 and 25, the display device 10 may include a substrate SUB, a circuit element layer disposed on the substrate SUB, and a light emitting element layer disposed on the circuit element layer.

The substrate SUB may be an insulating substrate. The substrate SUB may be made of an insulating material, such as glass, quartz, or polymer resin. The substrate SUB may be a rigid substrate but may be, in other embodiments, a flexible substrate configured to be bent, folded, rolled, or the like.

The circuit element layer may be disposed on the substrate SUB. The circuit element layer may include a lower metal layer 110, a semiconductor layer 120, a first conductive layer 130, a second conductive layer 140, a third conductive layer 150, and a plurality of insulating layers.

The lower metal layer 110 is disposed on the substrate SUB. The lower metal layer 110 may include a light blocking pattern BML. The light blocking pattern BML may be disposed to cover at least the channel part of an active layer ACT of the transistor TR from the lower area (e.g., from the lower side). However, the present disclosure is not limited thereto, and in other embodiments, the light blocking pattern BML may be omitted.

The lower metal layer 110 may include a material that blocks light. For example, the lower metal layer 110 may be formed of an opaque metal material that blocks (or substantially blocks) light transmission.

A buffer layer 161 may be disposed on the lower metal layer 110. The buffer layer 161 may be disposed to cover the entire surface of the substrate SUB on which the lower metal layer 110 is disposed. The buffer layer 161 may protect the plurality of transistors from moisture penetrating through the substrate SUB, which is vulnerable to moisture permeation.

The semiconductor layer 120 is disposed on the buffer layer 161. The semiconductor layer 120 may include the active layer ACT of the transistor TR. The active layer ACT of the transistor TR may be disposed to overlap the light blocking pattern BML of the lower metal layer 110.

The semiconductor layer 120 may include polycrystalline silicon, single crystal silicon, an oxide semiconductor, or the like. In an embodiment in which the semiconductor layer 120 includes polycrystalline silicon, the polycrystalline silicon may be formed by crystallizing amorphous silicon. When the semiconductor layer 120 includes polycrystalline silicon, the active layer ACT of the transistor TR may have a plurality of doped regions doped with impurities and a channel part therebetween. In another embodiment, the semiconductor layer 120 may include the oxide semiconductor. The oxide semiconductor may be, for example, indium-tin oxide (ITO), indium-zinc oxide (IZO), indium-gallium oxide (IGO), indium-zinc-tin oxide (IZTO), indium-gallium-zinc oxide (IGZO), indium-gallium-tin oxide (IGTO), indium-gallium-zinc-tin oxide (IGZTO) or the like.

A gate insulating layer 162 may be disposed on the semiconductor layer 120. The gate insulating layer 162 may act as the gate insulating layer of the transistor TR. The gate insulating layer 162 may be formed as a multi-layer in which inorganic layers including at least one inorganic material, for example, silicon oxide (SiOₓ), silicon nitride (SiNₓ), or silicon oxynitride (SiOₓN_{y}) are alternately stacked.

The first conductive layer 130 may be disposed on the gate insulating layer 162. The first conductive layer 130 may include a gate electrode GE of the transistor TR. The gate electrode GE may be disposed to overlap the channel part of the active layer ACT in the sixth direction DR6, that is, the thickness direction of the substrate SUB.

A first interlayer insulating layer 163 may be disposed on the first conductive layer 130. The first interlayer insulating layer 163 may be disposed to cover the gate electrode GE. The first interlayer insulating layer 163 may act as the insulating layer between the first conductive layer 130 and other layers disposed thereon and may protect the first conductive layer 130.

The second conductive layer 140 may be disposed on the first interlayer insulating layer 163. The second conductive layer 140 may include a drain electrode SD1 of the transistor TR and a source electrode SD2 of the transistor TR.

The drain electrode SD1 and the source electrode SD2 of the transistor TR may be electrically connected to both end areas of the active layer ACT of the transistor TR through a contact hole (e.g., a contact opening) penetrating the first interlayer insulating layer 163 and the gate insulating layer 162, respectively. In addition, the source electrode SD2 of the transistor TR may be electrically connected to the light blocking pattern BML of the lower metal layer 110 through another contact hole (e.g., another contact opening) penetrating the first interlayer insulating layer 163, the gate insulating layer 162, and the buffer layer 161.

A second interlayer insulating layer 164 may be disposed on the second conductive layer 140. The second interlayer insulating layer 164 may be disposed to cover the drain electrode SD1 of the transistor TR and the source electrode SD2 of the transistor TR. The second interlayer insulating layer 164 may act as the insulating layer between the second conductive layer 140 and other layers disposed thereon and may protect the second conductive layer 140.

The third conductive layer 150 may be disposed on the second interlayer insulating layer 164. The third conductive layer 150 may include a first voltage line VL1, a second voltage line VL2, and a conductive pattern CDP.

The first voltage line VL1 may overlap at least a portion of the drain electrode SD1 of the transistor TR in the thickness direction of the substrate SUB. A high potential voltage (e.g., a first power supply voltage) supplied to the transistor TR may be applied to the first voltage line VL1.

The second voltage line VL2 may be electrically connected to the second electrode 220 through a second electrode contact hole (e.g., a second contact opening) CTS penetrating a via layer 166 and a passivation layer 165, to be described below. A low potential voltage (e.g., a second power supply voltage) lower than the high potential voltage supplied to the first voltage line VL1 may be applied to the second voltage line VL2. For example, the high potential voltage (or the first power supply voltage) supplied to the transistor TR is applied to the first voltage line VL1, and the low potential voltage (or a second power supply voltage) lower than the high potential voltage supplied to the first voltage line VL1 may be applied to the second voltage line VL2.

The conductive pattern CDP may be electrically connected to the source electrode SD2 of the transistor TR. The conductive pattern CDP may be electrically connected to the source electrode SD2 of the transistor TR through the contact hole penetrating the second interlayer insulating layer 164. Also, the conductive pattern CDP may be electrically connected to the first electrode 210 through a first electrode contact hole (e.g., a first electrode contact opening) CTD penetrating the via layer 166 and the passivation layer 165, to be described below. The transistor TR may transfer the first power supply voltage applied from the first voltage line VL1 to the first electrode 210 through the conductive pattern CDP.

The passivation layer 165 may be disposed on the third conductive layer 150. The passivation layer 165 may be disposed to cover the third conductive layer 150. The passivation layer 165 may protect the third conductive layer 150.

Each of the buffer layer 161, the gate insulating layer 162, the first interlayer insulating layer 163, the second interlayer insulating layer 164, and the passivation layer 165 may be made of a plurality of alternately stacked inorganic layers. For example, some or all of the buffer layer 161, the gate insulating layer 162, the first interlayer insulating layer 163, the second interlayer insulating layer 164, and the passivation layer 165 may be formed of a double layer in which an inorganic layer including at least one of silicon oxide (SiOₓ), silicon nitride (SiNₓ), and silicon oxynitride (SiOₓN_{y}) is stacked, or a multilayer in which these are alternately stacked. However, the present disclosure is not limited thereto, and some or all of the buffer layer 161, the gate insulating layer 162, the first interlayer insulating layer 163, the second interlayer insulating layer 164, and the passivation layer 165 may be formed of one inorganic layer including the above-described insulating material.

The via layer 166 may be disposed on the passivation layer 165. The via layer 166 may include an organic insulating material, for example, an organic material, such as polyimide (PI). The via layer 166 may planarize the surface. Accordingly, the upper surface (or surface) of the via layer 166 on which the light emitting element layer, to be described later, is disposed may have a generally flat surface regardless of the shape or presence of a pattern disposed thereunder.

The light emitting element layer may be disposed on the circuit element layer. The light emitting element layer may be disposed on the via layer 166. The light emitting element layer may include a first bank 400, electrode layers 200 (e.g., 210, 220), a first insulating layer 510, the second bank 600, a plurality of light emitting elements ED and connection electrodes 710, 720.

A first bank 400 may be disposed on the via layer 166 in the light emitting area EMA. The first bank 400 may be directly disposed on one surface of the via layer 166. The first bank 400 may have a structure in which at least a portion thereof protrudes upwardly (e.g., one side in the sixth direction DR6) based on one surface of the via layer 166. The protruding portion of the first bank 400 may have an inclined side surface. The first bank 400 may change the propagation direction of light into an upper direction (e.g., a display direction) emitted from the light emitting element ED, including the inclined side, proceeding toward the side of the first bank 400.

The first bank 400 may include a first sub-bank 410 and a second sub-bank 420 spaced apart from each other. The first sub-bank 410 and the second sub-bank 420 provide a space therebetween in which the light emitting element ED is disposed and may act as reflective partition walls that change the propagation direction of the light emitted from the light emitting element ED to the display direction.

Although the side surface of the first bank 400 is illustrated as being inclined in a linear shape, the present disclosure is not limited thereto. For example, the side (or outer surface) of the first bank 400 may have a round shape, a semicircle, or a semielliptical shape. In an embodiment, the first bank 400 may include an organic insulating material, such as polyimide PI, but is not limited thereto.

The electrode layer 200 may have a shape extending in one direction and may be disposed to cross the light emitting area EMA and the sub area SA. The electrode layer 200 may transmit an electrical signal applied from the circuit element layer to the light emitting element ED to emit light. Also, the electrode layer 200 may be used to generate an electric field used in an alignment process of the plurality of light emitting elements ED.

The electrode layer 200 may be disposed on the first bank 400 and the via layer 166 exposed by the first bank 400. The electrode layer 200 in the light emitting area EMA may be disposed on the first bank 400, and the electrode layer 200 in the non-emission area may be disposed on the via layer 166 exposed by the first bank 400.

The electrode layer 200 may include the first electrode 210 and the second electrode 220. The first electrode 210 and the second electrode 220 may be spaced apart from each other.

The first electrode 210 may be disposed on the left side of each pixel PX in the plan view. The first electrode 210 may have a shape extending in the fifth direction DR5 in the plan view. The first electrode 210 may be disposed to cross the light emitting area EMA and the sub area SA. The first electrode 210 may extend in (e.g., may primarily extend in) the fifth direction DR5 in the plan view and may be separated from the first electrode 210 of the adjacent pixel PX in the fifth direction DR5 at the separation portion ROP of the sub area SA.

The second electrode 220 may be spaced apart from the first electrode 210 in the fourth direction DR4. The second electrode 220 may be disposed on one side (e.g., the right side) of each pixel PX in the fourth direction DR4 in the plan view. The second electrode 220 may have the shape extending in the fifth direction DR5 in the plan view. The second electrode 220 may be disposed to cross the light emitting area EMA and the sub area SA. The second electrode 220 may extend in the fifth direction DR5 in the plan view and may be separated from the second electrode 220 of the adjacent pixel PX in the fifth direction DR5 at the separation portion ROP of the sub area SA.

The first electrode 210 in the light emitting area EMA may be disposed on the first sub-bank 410, and the second electrode 220 may be disposed on the second sub-bank 420. The first electrode 210 may be extended outwardly from the first sub-bank 410 and may also be disposed on the via layer 166 exposed by the first sub-bank 410. Similarly, the second electrode 220 may be extended outwardly from the second sub-bank 420 and may also be disposed on the via layer 166 exposed by the second sub-bank 420. The first electrode 210 and the second electrode 220 may face each other in a spaced region between the first sub-bank 410 and the second sub-bank 420. The via layer 166 may be exposed in a region where the first electrode 210 and the second electrode 220 are spaced apart from each other.

The first electrode 210 may be spaced apart from the first electrode 210 of another pixel PX adjacent thereto in the fifth direction DR5 with the separation portion ROP interposed therebetween in the sub area SA. Similarly, the second electrode 220 may be spaced apart from the second electrode 220 of another pixel PX adjacent thereto in the fifth direction DR5 with the separation portion ROP interposed therebetween in the sub area SA. Accordingly, the first electrode 210 and the second electrode 220 may expose the via layer 166 in the separation portion ROP of the sub area SA.

The first electrode 210 may be electrically connected to the conductive pattern CDP of the circuit element layer through the first electrode contact hole CTD penetrating the via layer 166 and the passivation layer 165. For example, the first electrode 210 may contact the upper surface of the conductive pattern CDP exposed by the first electrode contact hole CTD. The first power supply voltage applied from the first voltage line VL1 may be transferred to the first electrode 210 through the conductive pattern CDP.

The second electrode 220 may be electrically connected to the second voltage line VL2 of the circuit element layer through the second electrode contact hole CTS penetrating the via layer 166 and the passivation layer 165. For example, the second electrode 220 may contact the upper surface of the second voltage line VL2 exposed by the second electrode contact hole CTS. The second power supply voltage applied from the second voltage line VL2 may be transmitted to the second electrode 220.

The electrode layer 200 may include a conductive material having high reflectance. For example, the electrode layer 200 includes a metal, such as silver (Ag), copper (Cu), aluminum (Al), or the like, and may include an alloy including aluminum (Al), nickel (Ni), lanthanum (La), or the like as the highly reflective material. The electrode layer 200 may reflect light emitted from the light emitting element ED that travels to the side surface of the first bank 400 in the upper direction of each pixel PX.

However, the present disclosure is not limited thereto, and the electrode layer 200 may further include a transparent conductive material. For example, the electrode layer 200 may include a material such as ITO, IZO, ITZO, or the like. In some embodiments, the electrode layer 200 may have a structure in which the transparent conductive material and the metal layer having a high reflectance are stacked in one or more layers or may be formed as a single layer including them. For example, the electrode layer 200 may have the stacked structure, such as ITO/Ag/ITO, ITO/Ag/IZO, or ITO/Ag/ITZO/IZO.

The first insulating layer 510 may be disposed on the via layer 166 on which the electrode layer 200 is formed. The first insulating layer 510 may protect the electrode layer 200 and may insulate the first electrode 210 and the second electrode 220 from each other.

The first insulating layer 510 may include an inorganic insulating material. For example, the first insulating layer 510 may include at least one of the inorganic insulating materials, such as silicon oxide (SiOₓ), silicon nitride (SiNₓ), silicon oxynitride (SiOₓN_{y}), aluminum oxide (AlₓO_{y}), aluminum nitride (AlN), or the like. The first insulating layer 510 made of the inorganic material may have a surface shape reflecting (or corresponding to) the pattern shape of the electrode layer 200 disposed thereunder. That is, the first insulating layer 510 may have a stepped structure according to the shape of the electrode layer 200 disposed under the first insulating layer 510. For example, the first insulating layer 510 may include the stepped structure in which a portion of the upper surface is recessed in a region where the first electrode 210 and the second electrode 220 are spaced apart from each other and face each other. Accordingly, the height of the top surface of the first insulating layer 510 disposed on the top of the first electrode 210 and the top of the second electrode 220 may be higher than the height of the top surface of the first insulating layer 510 disposed on the via layer 166 in which the first electrode 210 and the second electrode 220 are not disposed. In this specification, a relative comparison of the height of the upper surface of any layer may be made by the height measured from a flat reference surface (e.g., the upper surface of the via layer 166) without a lower stepped structure.

The first insulating layer 510 may include a first contact part (e.g., a first contact opening) CT1 exposing a portion of the top surface of the first electrode 210 and a second contact part (e.g., a second contact opening) CT2 exposing a portion of the top surface of the second electrode 220 in the sub-area SA. The first electrode 210 may be electrically connected to a first connection electrode 710, to be described later, through the first contact part CT1 penetrating the first insulating layer 510 in the sub-region SA, and the second electrode 220 may be electrically connected to a second connection electrode 720, to be described later, through the second contact part CT2 penetrating the first insulating layer 510 in the sub-region SA.

The second bank 600 may be disposed on the first insulating layer 510. The second bank 600 may be arranged in a grid pattern including portions extending in the fourth and fifth directions DR4 and DR5 in the plan view.

The second bank 600 may be disposed across the boundary of each pixel PX to distinguish adjacent pixels PX and may separate the light emitting area EMA and the sub-area SA. In addition, the second bank 600 is formed to have a greater height than the first bank 400, and thus, the ink in which the plurality of light emitting elements ED are dispersed may be injected (or deposited) into the light emitting area EMA without being mixed into (or introduced into) the adjacent pixels PX in the inkjet printing process for aligning the light emitting element ED during the manufacturing process of the display device 10.

The plurality of light emitting elements ED may be disposed in the light emitting area EMA. The plurality of light emitting elements ED may not be disposed in the sub-area SA.

The plurality of light emitting elements ED may be disposed on the first insulating layer 510 between the first sub-bank 410 and the second sub-bank 420. The plurality of light emitting elements ED may be disposed between the first electrode 210 and the second electrode 220 on the first insulating layer 510.

The light emitting element ED may have the shape extending in one direction and both ends of the light emitting element ED may be disposed on the first electrode 210 and the second electrode 220, respectively. For example, the plurality of light emitting elements ED may be disposed such that one end of the light emitting element ED is disposed on the first electrode 210 and the other end (e.g., the opposite end) of the light emitting element ED is disposed on the second electrode 220.

The length of each light emitting element ED in the longitudinal direction (e.g., the fourth direction DR4 in the drawing) may be smaller than the shortest distance between the first sub-bank 410 and the second sub-bank 420 spaced apart in the fourth direction DR4. Also, the length of each light emitting element ED may be greater than the shortest distance between the first electrode 210 and the second electrode 220 spaced apart in the fourth direction DR4. The distance in the fourth direction DR4 between the first sub-bank 410 and the second sub-bank 420 is larger than the length of each light emitting element ED, and the distance in the fourth direction DR4 between the first electrode 210 and the second electrode 220 is smaller than the length of each light emitting element ED so that the plurality of light emitting elements ED may be disposed so that both ends thereof are respectively disposed on the first electrode 210 and the second electrode 220 in the region between the first sub-bank 410 and the second sub-bank 420.

The plurality of light emitting elements ED may be spaced apart from each other along the fifth direction DR5 in which the first electrode 210 and the second electrode 220 are extended and may be aligned substantially parallel to each other.

A second insulating layer 520 may be disposed on the light emitting element ED. The second insulating layer 520 may be partially disposed on the light emitting element ED to expose both ends of the light emitting element ED. The second insulating layer 520 may be disposed to partially cover the outer surface of the light emitting element ED so as to not cover (e.g., so as to expose) one end and the other end of the light emitting element ED.

A portion of the second insulating layer 520 disposed on the light emitting element ED may form a linear or island-shaped pattern in each pixel PX by being disposed to extend in the fifth direction DR5 on the first insulating layer 510 on a plane. The second insulating layer 520 may protect the light emitting element ED and may fix the light emitting element ED in the manufacturing process of the display device 10. In addition, the second insulating layer 520 may be disposed to fill a space between the light emitting element ED and the first insulating layer 510 thereunder.

The connection electrode 700 may be disposed on the second insulating layer 520. The connection electrode 700 may be disposed on the light emitting element ED on which the first insulating layer 510 is disposed. The connection electrode 700 may include the first connection electrode 710 and the second connection electrode 720 spaced apart from each other.

The first connection electrode 710 may be disposed on the first electrode 210 in the light emitting area EMA. The first connection electrode 710 may have the shape extending in the fifth direction DR5 on the first electrode 210. The first connection electrode 710 may be in contact with the first electrode 210 and one end of the light emitting element ED, respectively.

The first connection electrode 710 is in contact with the first electrode 210 exposed by the first contact part CT1 penetrating the first insulating layer 510 in the sub-area SA and may contact one end of the light emitting element ED in the light emitting area EMA. That is, the first connection electrode 710 may electrically connect the first electrode 210 and one end of the light emitting element ED.

The second connection electrode 720 may be disposed on the second electrode 220 in the light emitting area EMA. The second connection electrode 720 may have the shape extending in the fifth direction DR5 on the second electrode 220. The second connection electrode 720 may be in contact with the second electrode 220 and the other end of the light emitting element ED, respectively.

The second connection electrode 720 is in contact with the second electrode 220 exposed by the second contact part CT2 penetrating the first insulating layer 510 in the sub-area SA and may contact the other end of the light emitting element ED in the light emitting area EMA. That is, the second connection electrode 720 may electrically connect the second electrode 220 and the other end of the light emitting element ED.

The first connection electrode 710 and the second connection electrode 720 may be spaced apart from each other on the light emitting element ED. For example, the first connection electrode 710 and the second connection electrode 720 may be spaced apart from each other with the second insulating layer 520 interposed therebetween. The first connection electrode 710 and the second connection electrode 720 may be electrically insulated from each other.

The first connection electrode 710 and the second connection electrode 720 may include the same material. For example, each of the first connection electrode 710 and the second connection electrode 720 may include a conductive material. For example, the first connection electrode 710 and the second connection electrode 720 may include ITO, IZO, ITZO, aluminum (Al), or the like. For example, each of the first connection electrode 710 and the second connection electrode 720 may include the transparent conductive material. The first connection electrode 710 and the second connection electrode 720 each include the transparent conductive material. Therefore, the light emitted from the light emitting element ED may pass through the first connection electrode 710 and the second connection electrode 720 and proceed toward the first electrode 210 and the second electrode 220 and may be reflected from surfaces of the first electrode 210 and the second electrode 220.

The first connection electrode 710 and the second connection electrode 720 may include the same material and may be formed in (or of) the same layer. The first connection electrode 710 and the second connection electrode 720 may be concurrently (or simultaneously) formed through the same process.

A third insulating layer 530 may be disposed on the connection electrode 700. The third insulating layer 530 may cover the light emitting element layer disposed thereunder. The third insulating layer 530 may cover the first bank 400, the electrode layer 200, the first insulating layer 510, the plurality of light emitting elements ED, and the connection electrode 700. The third insulating layer 530 may be disposed on the second bank 600 to also cover the second bank 600.

The third insulating layer 530 may protect the light emitting element layer disposed thereunder from foreign substances, such as moisture, oxygen, or particles. The third insulating layer 530 may protect the first bank 400, the electrode layer 200, the first insulating layer 510, the plurality of light emitting elements ED, and the connection electrode 700.

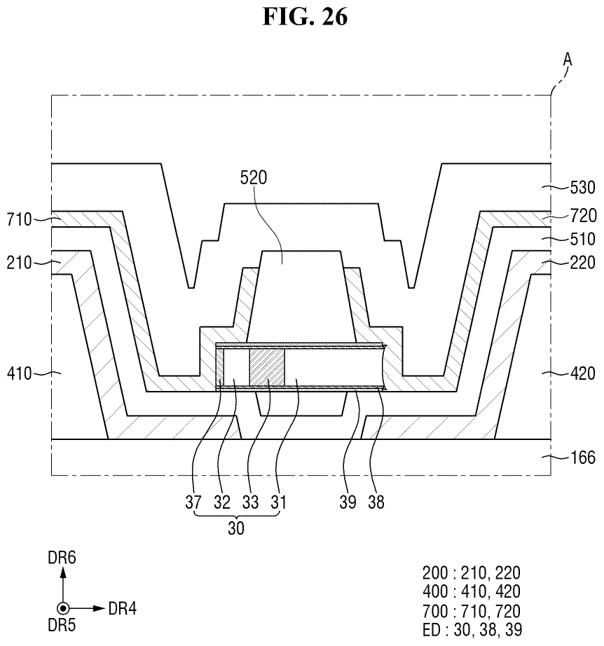

FIG. 26 is an enlarged cross-sectional view of the area A of FIG. 25.

Referring to FIG. 26, the light emitting element ED may be disposed so that the extending direction of the light emitting element ED is parallel to one surface of the substrate SUB. The plurality of semiconductor layers included in the light emitting element ED may be sequentially disposed along a direction parallel to the top surface of the substrate SUB (or the top surface of the via layer 166). For example, the first semiconductor layer 31, the light emitting layer 33, and the second semiconductor layer 32 of the light emitting element ED may be sequentially disposed to be parallel to the top surface of the substrate SUB.

In the light emitting element ED, the first semiconductor layer 31, the light emitting layer 33, the second semiconductor layer 32, and the element electrode layer 37 may be sequentially formed in a direction parallel to the top surface of the substrate SUB on a cross-section crossing both ends of the light emitting element ED. In addition, the first element insulating layer 38 and the second element insulating layer 39 surrounding the light emitting element ED may be disposed along the sixth direction DR6. In the present specification, a direction parallel to the upper surface of the substrate SUB may be the fourth direction DR4 or the fifth direction DR5, and in the drawing, the plurality of semiconductor layers are sequentially disposed along the fourth direction DR4 in the light emitting element ED.

One end surface (e.g., the first end surface EF1 in FIG. 2) of the light emitting element ED is disposed on the first electrode 210, and the other end surface (e.g., the second end surface EF2 in FIG. 2) of the light emitting element ED may be disposed on the second electrode 220. However, the present disclosure is not limited thereto, and one end surface of the light emitting element ED may be disposed on the second electrode 220, and the other end surface may be disposed on the first electrode 210.

The second insulating layer 520 may be disposed on the light emitting element ED. The second insulating layer 520 may be disposed to surround the outer surface of the light emitting element ED. The second insulating layer 520 is disposed on the second element insulating layer 39 of the light emitting element ED and may surround the outer surface of the second element insulating layer 39 of the light emitting element ED facing the display direction DR6.

The second insulating layer 520 is disposed to surround the outer surface of the light emitting element ED (e.g., the second element insulating layer 39 of the light emitting element ED) in the region where the light emitting element ED is disposed, and the second insulating layer 520 may be disposed on the first insulating layer 510 exposed by the light emitting element ED in the region where the light emitting element ED is not disposed.

The first connection electrode 710 may contact one end surface (e.g., the first end surface EF1) of the light emitting element ED exposed by the second insulating layer 520. For example, the first connection electrode 710 may be disposed to surround one end surface of the light emitting element ED exposed by the second insulating layer 520. The first connection electrode 710 may contact the second element insulating layer 39 and the element electrode layer 37 surrounding the outer surface of the light emitting element ED.

The second connection electrode 720 may contact the other end surface (e.g., the second end surface EF2) of the light emitting element ED exposed by the second insulating layer 520. For example, the second connection electrode 720 may be disposed to surround the other end surface of the light emitting element ED exposed by the second insulating layer 520. The second connection electrode 720 may contact the second element insulating layer 39 and the first semiconductor layer 31 of the light emitting element ED.

The first connection electrode 710 and the second connection electrode 720 may be spaced apart from each other with the second insulating layer 520 interposed therebetween. The first connection electrode 710 and the second connection electrode 720 may expose at least a portion of an upper surface of the second insulating layer 520.

According to embodiments of the present disclosure, the luminous efficiency of the display device 10 including the light emitting element ED may be improved. When there is the step difference on the lower surface of the first semiconductor layer 31 of the light emitting element ED, the light emitting element ED may be aligned to one side, a contact area between the light emitting element ED and the connection electrodes 710 and 720 may be reduced, or poor contact may occur. According to embodiments of the present disclosure, because the step of the lower surface of the first semiconductor layer 31 of the light emitting element ED is reduced or minimized, the light emitting element ED is aligned with the center between the first electrode 210 and the second electrode 220, a contact defect with the connection electrodes 710 and 720 is minimized, and the luminous efficiency of the display device 10 is increased when the light emitting element ED is aligned with the display device 10.

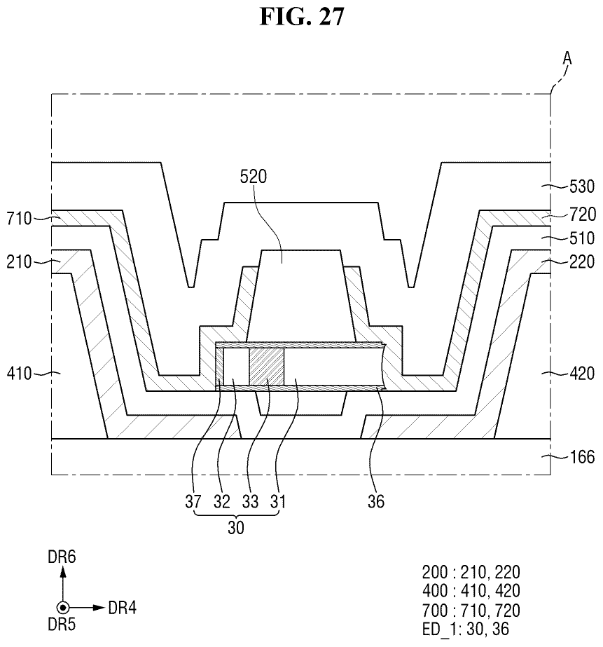

FIG. 27 is an enlarged cross-sectional view of the area A of FIG. 25 according to another embodiment.

Referring to FIG. 27, the light emitting element ED_1 may be disposed such that the extending direction of the light emitting element ED_1 is parallel to one surface of the substrate SUB. The plurality of semiconductor layers included in the light emitting element ED_1 may be sequentially disposed along the direction parallel to the top surface of the substrate SUB (or the top surface of the via layer 166). For example, the first semiconductor layer 31, the light emitting layer 33, and the second semiconductor layer 32 of the light emitting element ED_1 may be sequentially disposed to be parallel to the top surface of the substrate SUB. The element insulating layer 36 may be disposed to surround the light emitting element core 30.

One end surface (e.g., the first end surface EF1) of the light emitting element ED_1 may be disposed on the first electrode 210, the other end surface (e.g., the second end surface EF2) of the light emitting element ED_1 may be disposed on the second electrode 220. However, the present disclosure is not limited thereto, and one end of the light emitting element ED_1 may be disposed on the second electrode 220, and the other end of the light emitting element ED_1 may be disposed on the first electrode 210.

The second insulating layer 520 may be disposed on the light emitting element ED_1. The second insulating layer 520 may be disposed to surround the outer surface of the light emitting element ED_1. The second insulating layer 520 may be disposed on the element insulating layer 36 of the light emitting element ED_1 and may surround the outer surface of the element insulating layer 36 of the light emitting element ED_1 facing the display direction DR6.

The first connection electrode 710 may contact one end of the light emitting element ED_1 exposed by the second insulating layer 520. For example, the first connection electrode 710 may be disposed to surround one end surface of the light emitting element ED_1 exposed by the second insulating layer 520. The first connection electrode 710 may contact the element insulating layer 36 and the element electrode layer 37 surrounding the outer surface of the light emitting element ED_1.

The second connection electrode 720 may contact the other end of the light emitting element ED_1 exposed by the second insulating layer 520. For example, the second connection electrode 720 may be disposed to surround the other end surface of the light emitting element ED_1 exposed by the second insulating layer 520. The second connection electrode 720 may contact the element insulating layer 36 surrounding the outer surface of the light emitting element ED_1 and the first semiconductor layer 31.

It should be understood, however, that the aspects and features of embodiments of the present disclosure are not restricted to those set forth herein. The above and other aspects and features of the present disclosure will become more apparent to one of ordinary skill in the art to which the present disclosure pertains by referencing the claims, with equivalents thereof to be included within the scope thereof.

What is claimed is:

1. A light emitting element comprising:
a light emitting element core comprising a first semiconductor layer, a light emitting layer on the first semiconductor layer, and a second semiconductor layer on the light emitting layer; and
a first element insulating layer surrounding a side surface of the light emitting element core,
wherein an outer surface of the first element insulating layer has:
a first outer surface adjacent to one surface of the first semiconductor layer, the one surface of the first semiconductor layer being opposite to another surface of the first semiconductor layer facing the second semiconductor layer; and
a second outer surface farther away from a side surface of the first semiconductor layer than the first outer surface is.

2. The light emitting element of claim 1, wherein the other surface of the first semiconductor layer has a concave shape toward a center of the first semiconductor layer.

3. The light emitting element of claim 1, wherein a first diameter of the first element insulating layer having the first outer surface is smaller than a second diameter of the first element insulating layer having the second outer surface.

4. The light emitting element of claim 1, further comprising a second element insulating layer between the light emitting element core and the first element insulating layer and surrounding the side surface of the light emitting element core,
wherein a side surface of the first semiconductor layer is in contact with both the first element insulating layer and the second element insulating layer.

5. The light emitting element of claim 4, wherein the first element insulating layer has a first lower surface between the first outer surface and the one surface of the first semiconductor layer and a second lower surface between the first outer surface and the second outer surface.

6. The light emitting element of claim 5, wherein a first distance, which is a maximum distance between a first lower surface of the first element insulating layer and the other surface of the first semiconductor layer, is greater than a second distance, which is a maximum distance between a first lower surface of the first element insulating layer and a lower surface of the second element insulating layer.

7. The light emitting element of claim 6, wherein the first distance and the second distance are 100 nm or less.

8. The light emitting element of claim 5, wherein a first distance, which is a maximum distance between a first lower surface of the first element insulating layer and the other surface of the first semiconductor layer, is the same as a second distance, which is a maximum distance between a first lower surface of the first element insulating layer and a lower surface of the second element insulating layer.

9. The light emitting element of claim 4, wherein a first distance, which is a maximum distance between a first lower surface of the first element insulating layer and the other surface of the first semiconductor layer, is greater than a second distance, which is a maximum distance between a first lower surface of the first element insulating layer and a second lower surface of the first element insulating layer.

10. The light emitting element of claim 4, wherein one surface of the second element insulating layer is covered by the first element insulating layer.

11. The light emitting element of claim 4, wherein the side surface of the first semiconductor layer has a first side surface in contact with the first element insulating layer and a second side surface in contact with the second element insulating layer, and
wherein the first side surface is nearer to the other surface of the first semiconductor layer than the second side surface is.

12. The light emitting element of claim 1, wherein a first thickness of the first element insulating layer having the first outer surface is the same as a second thickness of the first element insulating layer having the second outer surface.

13. The light emitting element of claim 1, wherein a first thickness of the first element insulating layer at the first outer surface is less than a second thickness of the first element insulating layer at the second outer surface.

14. The light emitting element of claim 1, wherein the light emitting element core further comprises an element electrode layer on the second semiconductor layer,
wherein a side surface of the element electrode layer protrudes outwardly from a side surface of the first semiconductor layer.

15. A method for fabricating the light emitting element, the method comprising:
forming a first stacked structure comprising a first semiconductor material layer, a light emitting material layer, and a second semiconductor material layer on a substrate;
forming a second stacked structure comprising a first semiconductor layer, a light emitting layer, and a second semiconductor layer by etching the first stacked structure in a direction perpendicular to the substrate;
forming a first element insulating layer surrounding an outer surface of the first semiconductor layer;
a first etching of etching an inclined surface of the first semiconductor layer exposed by the first element insulating layer;
forming a second element insulating layer on a first side surface of the first semiconductor layer exposed through the first etching and a second side surface surrounded by the first element insulating layer; and
separating the first semiconductor layer from the substrate.

16. The method of claim 15, wherein the inclined surface of the first semiconductor layer is inclined by 120° to 140° from the substrate.

17. The method of claim 16, wherein the separating the first semiconductor layer from the substrate comprises forming a remaining first semiconductor layer on the substrate.

18. The method of claim 17, wherein the remaining first semiconductor layer includes a protrusion protruding from an upper surface of the substrate to have a height of 100 nm or less.

19. The method of claim 15, wherein the first side surface and the second side surface of the first semiconductor layer are vertically aligned with the substrate.

20. The method of claim 15, wherein the forming of the second element insulating layer comprises:
forming the second element insulating layer on an upper surface of the first semiconductor layer exposed between adjacent ones of the second stacked structures; and
etching the second element insulating layer on the upper surface of the first semiconductor layer.

21. The method of claim 20, wherein an etching process of the second element insulating layer is a dry etching method, and
wherein an etching process of the inclined surface of the first semiconductor layer is a wet etching method.

22. A display device comprising:
a first electrode and a second electrode on a substrate and spaced apart from each other; and
a light emitting element between the first electrode and the second electrode, the light emitting element comprising:
a first semiconductor layer;
a light emitting layer on the first semiconductor layer;
a light emitting element core comprising a second semiconductor layer on the light emitting layer; and
a first element insulating layer surrounding a side surface of the light emitting element core,
wherein the first element insulating layer has a first outer surface adjacent to one surface of the first semiconductor layer, the one surface of the first semiconductor layer being opposite to another surface of the first semiconductor layer facing the second semiconductor layer, and a second outer surface farther away from a side surface of the first semiconductor layer than the first outer surface is.

23. The display device of claim 22, further comprising a first connection electrode in contact with a first end of the light emitting element; and
a second connection electrode in contact with a second end of the light emitting element,
wherein the second end of the light emitting element and the second connection electrode are concave toward a center of the light emitting element.
